(19) United States
(12) Patent Application Publication
(10) Pub. No.: US 2025/0355529 A1
(43) Pub. Date: Nov. 20, 2025

(54) ELECTRONIC DEVICE

(71) Applicant: Samsung Display Co., Ltd., Yongin-si (KR)

(72) Inventors: BONGIL KANG, Yongin-si (KR); MIN-HONG KIM, Yongin-si (KR); SANGKOOK KIM, Yongin-si (KR); YERIN OH, Yongin-si (KR)

(21) Appl. No.: 19/092,765

(22) Filed: Mar. 27, 2025

(30) Foreign Application Priority Data
May 17, 2024 (KR) 10-2024-0064476

(51) Int. Cl. G06F 3/044; G06F 3/041

(52) U.S. Cl. CPC G06F 3/0446; G06F 3/04166; G06F 2203/04106

(57) ABSTRACT

An electronic device is provided. An electronic device may include a sensor layer defining a sensing area, and a peripheral area adjacent to the sensing area, and including first electrodes in the sensing area, and arranged in a first direction, second electrodes in the sensing area, and arranged in a second direction crossing the first direction, third electrodes in the sensing area, and arranged in the first direction, first trace lines electrically connected to the first electrodes in one-to-one correspondence, second trace lines electrically connected to the second electrodes in one-to-one correspondence, a first loop trace line electrically connected to the third electrodes, second loop trace lines electrically connected to the third electrodes, and a third loop trace line electrically connected to one of the third electrodes.

### CROSS-REFERENCE TO RELATED APPLICATION

The present application claims priority to, and the benefit of, Korean Patent Application No. 10-2024-0064476, filed on May 17, 2024, in the Korean Intellectual Property Office, the entire disclosure of which is incorporated herein by reference.

### BACKGROUND

### 1. Field

Aspects of one or more embodiments of the present disclosure described herein relate to an electronic device having improved pen charging performance.

### 2. Description of the Related Art

Multimedia electronic devices, such as a television (TV), a mobile phone, a tablet computer, a laptop, a navigation system, and/or a game console, include a display device for displaying an image. In addition to a general input method such as a button, a keyboard, and/or a mouse, electronic devices may include a sensor layer (or an input sensor) capable of providing a touch-based input method that allows a user to input information or commands suitably and intuitively. The sensor layer may sense a touch and/or pressure by the user. Meanwhile, the demand of use of a pen for a more detailed input for the user who is accustomed to inputting information utilizing a writing instrument and/or a specific application (e.g., an application for sketching or drawing) is increasing.

### SUMMARY

Aspects of one or more embodiments of the present disclosure provide an electronic device having improved pen charging performance.

According to one or more embodiments, an electronic device includes a sensor layer defining a sensing area, and a peripheral area adjacent to the sensing area, and including first electrodes in the sensing area, and arranged in a first direction, second electrodes in the sensing area, and arranged in a second direction crossing the first direction, third electrodes in the sensing area, and arranged in the first direction, first trace lines electrically connected to the first electrodes in one-to-one correspondence, second trace lines electrically connected to the second electrodes in one-to-one correspondence, a first loop trace line electrically connected to the third electrodes, second loop trace lines electrically connected to the third electrodes, and a third loop trace line electrically connected to one of the third electrodes.

The one of the third electrodes may be closest to the peripheral area among the third electrodes, and may be electrically connected to the first loop trace line and to one of the second loop trace lines.

The electronic device may further include a sensor driver configured to drive the sensor layer, and configured to selectively operate in a first mode for sensing a touch input or in a second mode for sensing a pen input, the second mode including a charging drive mode and a pen-sensing drive mode.

In the charging drive mode, the sensor driver may be configured to provide a signal to one of a first pad connected to the one of the second loop trace lines, or a second pad connected to the third loop trace line, to the exclusion of the other one of the first pad or the second pad.

In the charging drive mode, the sensor driver may be configured to provide a signal to a first pad connected to the one of the second loop trace lines, and to a second pad connected to the third loop trace line.

The sensor layer may further include a fourth loop trace line electrically connected to the one of the third electrodes.

In the charging drive mode, the sensor driver may be configured to provide a signal to at least one of a first pad connected to the one of the second loop trace lines, a second pad connected to the third loop trace line, or a third pad connected to the fourth loop trace line.

The sensor layer may further include a fourth loop trace line electrically connected to another one of the third electrodes.

A first portion of the third loop trace line may be at the sensing area, and a second portion of the third loop trace line may be at the peripheral area.

The first portion of the third loop trace line may overlap at least one of the first electrodes.

The second portion of the third loop trace line may be between the sensing area and the first loop trace line in plan view.

The sensor layer may further include fourth electrodes in the sensing area, and arranged in the second direction, and an auxiliary trace line electrically connected to the fourth electrodes.

The third loop trace line may be between the auxiliary trace line and at least one of the second trace lines in plan view.

A width of the sensing area in the first direction may be greater than a width of the sensing area in the second direction, wherein the third loop trace line is separated from the sensing area in the first direction.

According to one or more embodiments, an electronic device includes a sensor layer defining a sensing area, and a peripheral area adjacent to the sensing area, and including first electrodes in the sensing area, and arranged in a first direction, second electrodes in the sensing area, and arranged in a second direction crossing the first direction, third electrodes in the sensing area, and arranged in the first direction, and trace lines electrically connected to the first electrodes, to the second electrodes, and to the third electrodes, and including a first loop trace line connected to one end of one of the third electrodes, a second loop trace line connected to another end of the one of the third electrodes, and a third loop trace line connected to the one of the third electrodes.

The trace lines may further include a fourth loop trace line connected to the one of the third electrodes.

The electronic device may further include a sensor driver configured to drive the sensor layer, and configured to selectively operate in a first mode of sensing a touch input, or a second mode of sensing a pen input, the second mode including a charging drive mode and a pen-sensing drive mode.

In the charging drive mode, the sensor driver may be configured to provide a signal to one of a first pad connected to the second loop trace line, or a second pad connected to the third loop trace line, to the exclusion of the other one of the first pad or the second pad.

In the charging drive mode, the sensor driver may be configured to provide a signal to a first pad connected to the second loop trace line, and to a second pad connected to the third loop trace line.

The trace lines may further include a fourth loop trace line connected to another one of the third electrodes, wherein the third loop trace line is separated from the fourth loop trace line with the sensing area therebetween in plan view.

### BRIEF DESCRIPTION OF THE DRAWINGS

The above and other aspects of the present disclosure will become apparent by describing in detail embodiments thereof with reference to the accompanying drawings.

FIG. 1A is a perspective view of an electronic device according to one or more embodiments of the present disclosure.

FIG. 1B is a rear perspective view of the electronic device according to one or more embodiments of the present disclosure.

FIG. 2 is a perspective view of the electronic device according to one or more embodiments of the present disclosure.

FIG. 3 is a perspective view of the electronic device according to one or more embodiments of the present disclosure.

FIG. 4 is a schematic cross-sectional view of a display panel according to one or more embodiments of the present disclosure.

FIG. 5 is a view for describing an operation of the electronic device according to one or more embodiments of the present disclosure.

FIG. 6A is a cross-sectional view of the display panel according to one or more embodiments of the present disclosure.

FIG. 6B is a cross-sectional view of a sensor layer according to one or more embodiments of the present disclosure.

FIG. 7 is a plan view of the display panel according to one or more embodiments of the present disclosure.

FIG. 8A is a plan view illustrating a first conductive layer of two sensors according to one or more embodiments of the present disclosure.

FIG. 8B is a plan view illustrating a second conductive layer of the two sensors according to one or more embodiments of the present disclosure.

FIG. 9 is a cross-sectional view of the sensor layer along the line I-I′ illustrated in FIGS. 8A and 8B according to one or more embodiments of the present disclosure.

FIG. 10A is an enlarged plan view of area AA′ illustrated in FIG. 8A.

FIG. 10B is an enlarged plan view of area BB′ illustrated in FIG. 8B.

FIG. 11A is a view illustrating an operation of a sensor driver according to one or more embodiments of the present disclosure.

FIG. 11B is a view illustrating the operation of the sensor driver according to one or more embodiments of the present disclosure.

FIG. 12 is a view for describing a first mode according to one or more embodiments of the present disclosure.

FIG. 13 is a view for describing a second mode according to one or more embodiments of the present disclosure.

FIG. 14A is a graph depicting a waveform of a first signal according to one or more embodiments of the present disclosure.

FIG. 14B is a graph depicting a waveform of a second signal according to one or more embodiments of the present disclosure.

FIG. 15A is a table representing signals provided to the sensor layer according to one or more embodiments of the present disclosure.

FIG. 15B is a table representing signals provided to the sensor layer according to one or more embodiments of the present disclosure.

FIG. 16 is a view for describing a second mode according to one or more embodiments of the present disclosure.

FIG. 17 is a view for describing a second mode based on the sensor according to one or more embodiments of the present disclosure.

FIG. 18A is a plan view illustrating the first conductive layer of the two sensors according to one or more embodiments of the present disclosure.

FIG. 18B is a plan view illustrating the second conductive layer of the two sensors according to one or more embodiments of the present disclosure.

FIG. 19 is a plan view of a display panel according to one or more embodiments of the present disclosure.

FIG. 20A is a table representing signals provided to the sensor layer according to one or more embodiments of the present disclosure.

FIG. 20B is a table representing signals provided to the sensor layer according to one or more embodiments of the present disclosure.

FIG. 21 is a plan view of the display panel according to one or more embodiments of the present disclosure.

FIG. 22 is a table representing signals provided to the sensor layer according to one or more embodiments of the present disclosure.

### DETAILED DESCRIPTION

Aspects of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

One or more suitable embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved shapes and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit or scope of the present disclosure.

In the detailed description, for the purposes of explanation, numerous specific details are set forth to provide a thorough understanding of one or more suitable embodiments. It is apparent, however, that one or more suitable embodiments may be practiced without these specific details or with one or more equivalent arrangements. In other instances, well-known structures and devices are shown in block diagram form to avoid unnecessarily obscuring one or more suitable embodiments.

Spatially relative terms, such as “beneath,” “below,” “lower,” “under,” “above,” “upper,” and the like, may be utilized herein for ease of explanation to describe one element's relationship to another element(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements would then be oriented “above” the other elements. Thus, the example terms “below” and “under” can encompass both an orientation of above and below. The device may be otherwise oriented (e.g., rotated 90 degrees or at other orientations) and the spatially relative descriptors utilized herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, area, layer, part, portion, region, or component is referred to as being “formed on,” “disposed on,” “on,” “connected to,” “connected with,” or “coupled to” another element, area, layer, part, portion, region, or component, it can be directly formed on, disposed on, on, connected to, connected with, or coupled to the other element, area, layer, part, portion, region, or component, or indirectly formed on, disposed on, on, connected to, connected with, or coupled to the other element, area, layer, part, portion, region, or component, such that one or more intervening elements, areas, layers, parts, portions, regions, or components may be present. For example, when an element, layer, part, portion, region, or component is referred to as being “electrically connected” or “electrically coupled” to another element, layer, part, portion, region, or component, it can be directly electrically connected or coupled to the other element, layer, part, portion, region, or component, or intervening elements, layers, parts, portions, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As utilized herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

The same reference numerals refer to the same components. Further, in the drawings, the thickness, the ratio, and the dimension of components are exaggerated for effective description of technical contents. The expression “and/or” includes one or more combinations which associated components are capable of defining.

It will be understood that, although the terms “first”, “second”, etc. may be used herein to describe one or more suitable components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

Also, the terms “under”, “below”, “on”, “above”, etc. are used to describe the correlation of components illustrated in drawings. The terms that are relative in concept are described based on a direction illustrated in drawings.

The terminology utilized herein is for the purpose of describing particular embodiments only and is not intended to be limiting of the present disclosure. As utilized herein, the singular forms “a” and “an” are intended to include the plural forms as well, unless the context clearly indicates otherwise. It will be further understood that the terms “comprise,” “comprises,” “comprising,” “has,” “have,” “having,” “include,” “includes,” and “including,” when utilized in this specification, specify the presence of the stated features, integers, steps, operations, elements, and/or components, but do not preclude the presence or addition of one or more other features, integers, steps, operations, elements, components, and/or groups thereof.

As utilized herein, the term “substantially,” “about,” “approximately,” and similar terms are utilized as terms of approximation and not as terms of degree, and are intended to account for the inherent deviations in measured or calculated values that would be recognized by those of ordinary skill in the art. “About” or “approximately,” as utilized herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the one or more suitable components of these devices may be formed on one integrated circuit (IC) chip or on separate IC chips. Further, the one or more suitable components of these devices may be implemented on a flexible printed circuit film, a tape carrier package (TCP), a printed circuit board (PCB), or formed on one substrate.

In the present disclosure, it will be understood that the terms “include/includes/including,” “comprise/comprises/comprising,” or “have/has/having,” specifies the presence of stated features, integers, numbers, steps, operations, elements, and/or components, but do not preclude the presence or addition of one or more other features, integers, numbers, steps, operations, elements, components, and/or groups thereof. Additionally, the terms “include/includes/including,” “comprise/comprises/comprising,” or “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Terms “part” and “unit” mean a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, program code segments, drivers, firmwares, microcodes, circuits, data, database, data structures, tables, arrays, or variables.

Hereinafter, one or more embodiments of the present disclosure will be described with reference to the accompanying drawings.

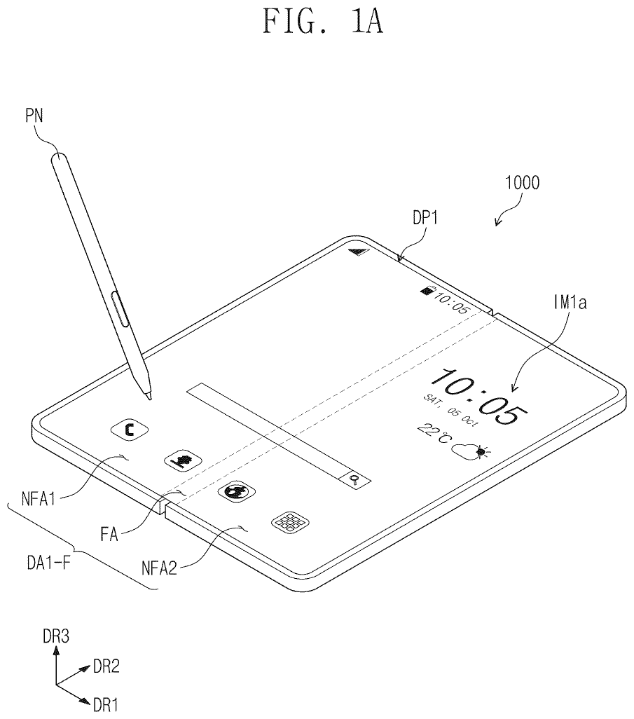

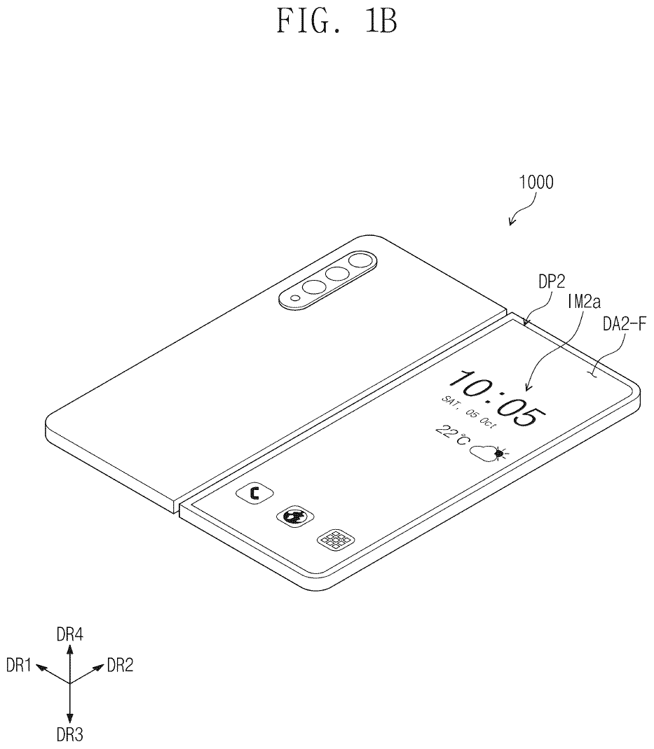

FIG. 1A is a perspective view of an electronic device 1000 according to one or more embodiments of the present disclosure. FIG. 1B is a rear perspective view of the electronic device 1000 according to one or more embodiments of the present disclosure.

Referring to FIGS. 1A and 1B, the electronic device 1000 may be a device that is activated according to an electrical signal. For example, the electronic device 1000 may display an image and sense inputs applied from the outside (e.g., an external input). The external input may be an input of the user. The input of the user may include one or more suitable types of external inputs, such as a portion of a human body of the user, a pen PN, a light, heat, and/or pressure.

The electronic device 1000 may include a first display panel DP1 and a second display panel DP2. The first display panel DP1 and the second display panel DP2 may be separate panels separated from each other (e.g., the first display panel DP1 may be separated from the second display panel DP2). The first display panel DP1 may be referred to as a main display panel, and the second display panel DP2 may be referred to as an auxiliary display panel or an external display panel.

The first display panel DP1 may include a first display (e.g., display unit) DA1-F, and the second display panel DP2 may include a second display DA2-F. An area of the second display panel DP2 may be smaller than an area of the first display panel DP1. To correspond to the sizes of the first display panel DP1 and the second display panel DP2, an area of the first display DA1-F may be larger than an area of the second display DA2-F.

In a state in which the electronic device 1000 is in an unfolded state, the first display DA1-F may have a plane substantially parallel to a first direction DR1 and a second direction DR2. A thickness direction of the electronic device 1000 may be parallel to a third direction DR3 intersecting the first direction DR1 and the second direction DR2. Thus, front surfaces (or upper surfaces) and rear surfaces (or lower surfaces) of members constituting the electronic device 1000 may be defined based on the third direction DR3.

The first display panel DP1 or the first display DA1-F may include a folding area FA that is folded or unfolded and a plurality of non-folding areas (NFA1 and NFA2) separated from (e.g., spaced apart from) each other with the folding area FA therebetween (e.g., the folding area FA is interposed between a first non-folding area NFA1 and a second non-folding area NFA2). The second display panel DP2 may overlap one of the plurality of non-folding areas (NFA1 and/or NFA2). For example, the second display panel DP2 may overlap the first non-folding area NFA1.

A display direction of a first image IM1a displayed on a portion of the first display panel DP1. For example, the first non-folding area NFA1 may be opposite to a display direction of a second image IM2a displayed on the second display panel DP2. For example, the first image IM1a may be displayed in the third direction DR3, and the second image IM2a may be displayed in a fourth direction DR4 that is opposite to the third direction DR3.

In one or more embodiments of the present disclosure, the folding area FA may be bent with respect to a folding axis extending in a direction parallel to long sides of the electronic device 1000, for example, a direction parallel to the second direction DR2. In a state in which the electronic device 1000 is folded, the folding area FA has a set curvature (e.g., a predetermined curvature) and a set radius of curvature (e.g., a predetermined radius of curvature).

The first non-folding area NFA1 and the second non-folding area NFA2 may face each other, and the electronic device 1000 is inner-folded, so that the first display DA1-F is reduced or prevented from being exposed to the outside. Alternatively, in one or more embodiments of the present disclosure, the electronic device 1000 may be outer-folded, so that the first display DA1-F is exposed to the outside. Alternatively, in one or more embodiments of the present disclosure, the electronic device 1000 may be inner-folded or outer-folded in an unfolded state.

FIG. 1A illustratively illustrates that one folding area FA is defined (provided or included) in the electronic device 1000, but the present disclosure is not limited thereto. For example, a plurality of folding axes and a plurality of folding areas corresponding thereto may be defined in the electronic device 1000, and the electronic device 1000 may be inner-folded or outer-folded in a state in which each of the plurality of folding areas is unfolded.

According to one or more embodiments of the present disclosure, even if (e.g., when) at least one of the first display panel DP1 and/or the second display panel DP2 does not include a digitizer, the at least one of the first display panel DP1 and/or the second display panel DP2 may sense an input by the pen PN. Thus, because the digitizer for sensing the pen PN is omitted, an increase in a thickness, an increase in a weight, and a decrease in flexibility of the electronic device 1000 caused by addition of the digitizer may not occur. Thus, the second display panel DP2 as well as the first display panel DP1 may be designed to sense the pen PN.

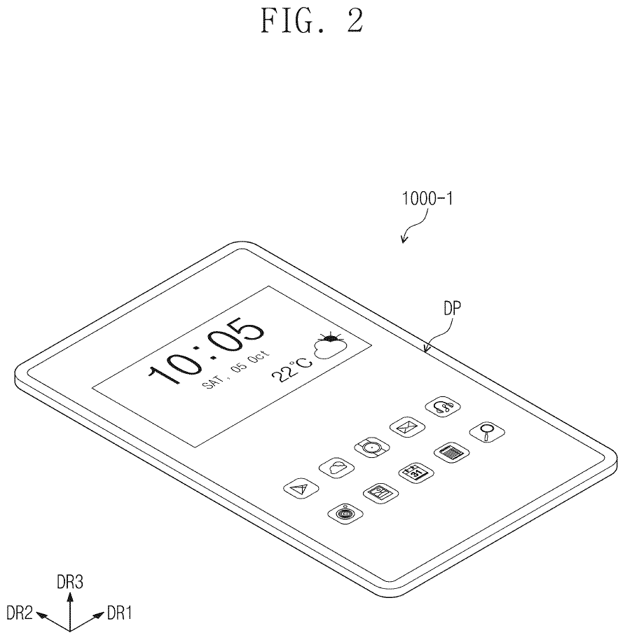

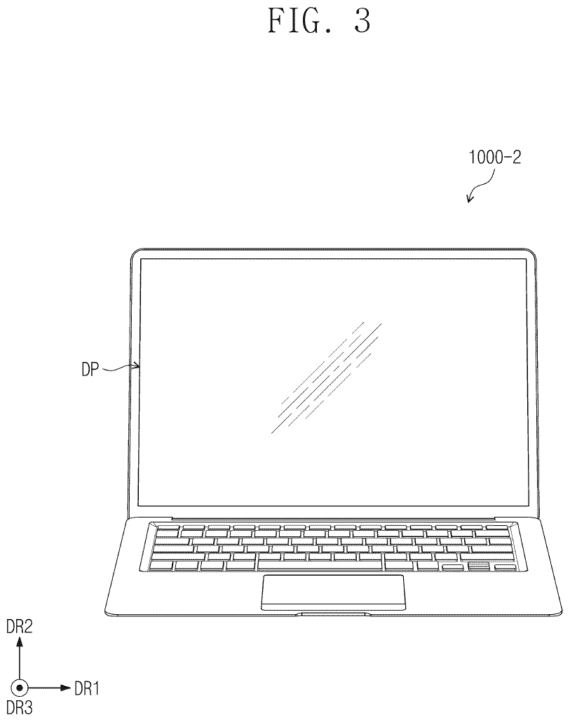

FIG. 2 is a perspective view of an electronic device 1000-1 according to one or more embodiments of the present disclosure. FIG. 3 is a perspective view of an electronic device 1000-2 according to one or more embodiments of the present disclosure.

FIG. 2 illustratively illustrates that the electronic device 1000-1 is a tablet, and the electronic device 1000-1 may include a display panel DP. FIG. 3 illustratively illustrates that the electronic device 1000-2 is a laptop, and the electronic device 1000-2 may include the display panel DP. Although FIG. 3 is the perspective view of an electronic device 1000-2, the coordinate axes included in FIG. 3 are displayed based on the display panel DP within the electronic device 1000-2.

In one or more embodiments of the present disclosure, the display panel DP may sense inputs applied from the outside (e.g., an external input). The external input may be an input of the user. The input of the user may include one or more suitable types of external inputs such as the portion of the human body of the user, the pen PN (see FIG. 1A), the light, the heat, and/or the pressure.

According to one or more embodiments of the present disclosure, the display panel DP may sense an input by the pen PN even if (e.g., when) the display panel DP does not include the digitizer. Thus, because the digitizer for sensing the pen PN is omitted, an increase in the thickness and an increase in the weight of the electronic device 1000-1 or 1000-2 caused by the addition of the digitizer may not occur.

FIG. 1A illustratively illustrates the foldable-type electronic device 1000, and FIG. 2 illustratively illustrates the bar-type electronic device 1000-1, but the present disclosure described below is not limited thereto. For example, the following descriptions may be applied to a curved type electronic device, a rollable type electronic device, a slidable type electronic device, and/or a stretchable type electronic device.

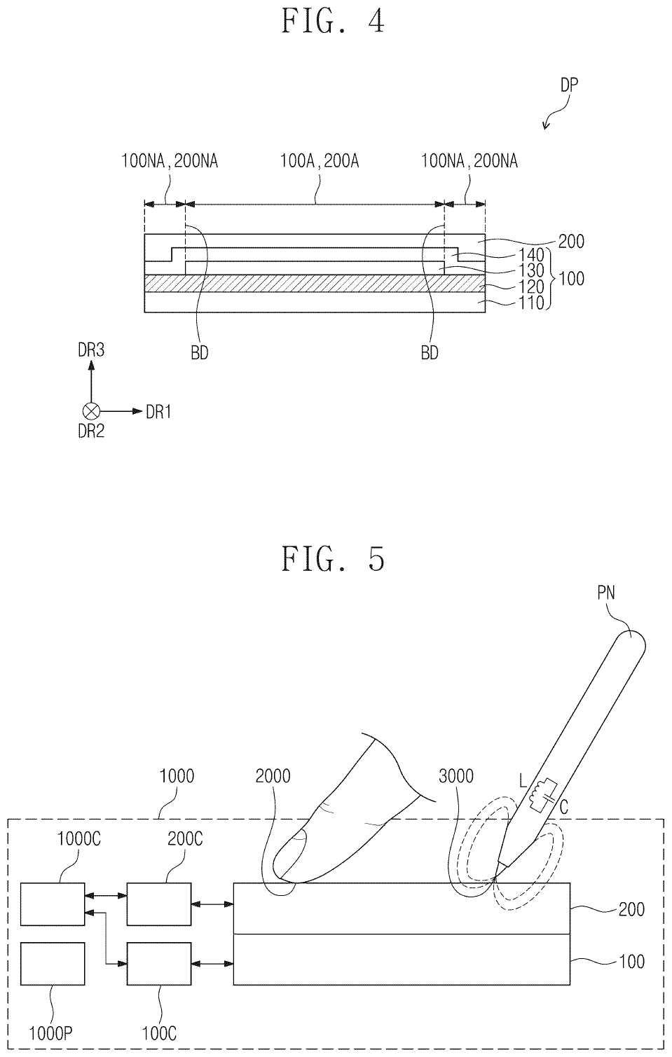

FIG. 4 is a schematic cross-sectional view of the display panel DP according to one or more embodiments of the present disclosure.

Referring to FIG. 4, the display panel DP may include a display layer 100 and a sensor layer 200.

The display layer 100 may be a component that substantially generates an image. A display area 100A and a non-display area 100NA adjacent to the display area 100A may be defined in the display layer 100. The image may be displayed in the display area 100A.

The display layer 100 may be a light-emitting display layer. For example, the display layer 100 may be an organic light-emitting display layer, an inorganic light-emitting display layer, an organic-inorganic light-emitting display layer, a quantum dot display layer, a micro-light-emitting diode (LED) display layer, and/or a nano-LED display layer. The display layer 100 may include a base layer 110, a circuit layer 120, a light-emitting element layer 130, and an encapsulation layer 140.

The base layer 110 may be a member that provides a base surface on which the circuit layer 120 is provided. The base layer 110 may have a multi-layer structure or a single-layer structure. The base layer 110 may be a glass substrate, a metal substrate, a silicon substrate, a polymer substrate, and/or the like, but the present disclosure is not limited thereto.

The circuit layer 120 may be provided on the base layer 110. The circuit layer 120 may include an insulating layer, a semiconductor pattern, a conductive pattern, a signal line, and/or the like. The insulating layer, a semiconductor layer, and a conductive layer may be on (e.g., formed on) the base layer 110 in a manner such as coating and deposition, and the insulating layer, the semiconductor layer, and the conductive layer may be selectively patterned through a plurality of photolithography processes.

The light-emitting element layer 130 may be provided on the circuit layer 120. The light-emitting element layer 130 may include a light-emitting element. For example, the light-emitting element layer 130 may include an organic light-emitting material, an inorganic light-emitting material, an organic-inorganic light-emitting material, a quantum dot, a quantum rod, a micro-LED, and/or a nano-LED.

The encapsulation layer 140 may be provided on the light-emitting element layer 130. The encapsulation layer 140 may protect the light-emitting element layer 130 from moisture, oxygen, and/or foreign substances such as dust particles.

The sensor layer 200 may be provided on the display layer 100. A sensing area 200A and a peripheral area 200NA adjacent to the sensing area 200A may be defined in the sensor layer 200. The sensing area 200A may overlap the display area 100A, and the peripheral area 200NA may overlap the non-display area 100NA.

In one or more embodiments of the present disclosure, a boundary BD between the display area 100A and the non-display area 100NA and the boundary BD between the sensing area 200A and the peripheral area 200NA may overlap each other. However, this is merely an example, and the present disclosure is not particularly limited thereto. For example, an area of the sensing area 200A may be larger than an area of the display area 100A, or the area of the display area 100A may be larger than the area of the sensing area 200A.

The sensor layer 200 may sense an external input applied from an external unit. The sensor layer 200 may be an integrated sensor provided (e.g., formed) continuously during a process of manufacturing the display layer 100, or the sensor layer 200 may be an external sensor attached to the display layer 100. The sensor layer 200 may be referred to as a sensor, an input sensing layer, an input sensing panel, an electronic device for sensing input coordinates, and/or the like.

According to one or more embodiments of the present disclosure, the sensor layer 200 may sense both inputs for a passive input means, such as the human body of the user and an input device that generates a magnetic field having a set predetermined resonant frequency (e.g., a predetermined resonant frequency). The input device may be referred to as a pen, an input pen, a magnetic pen, a stylus pen, and/or an electromagnetic resonance pen.

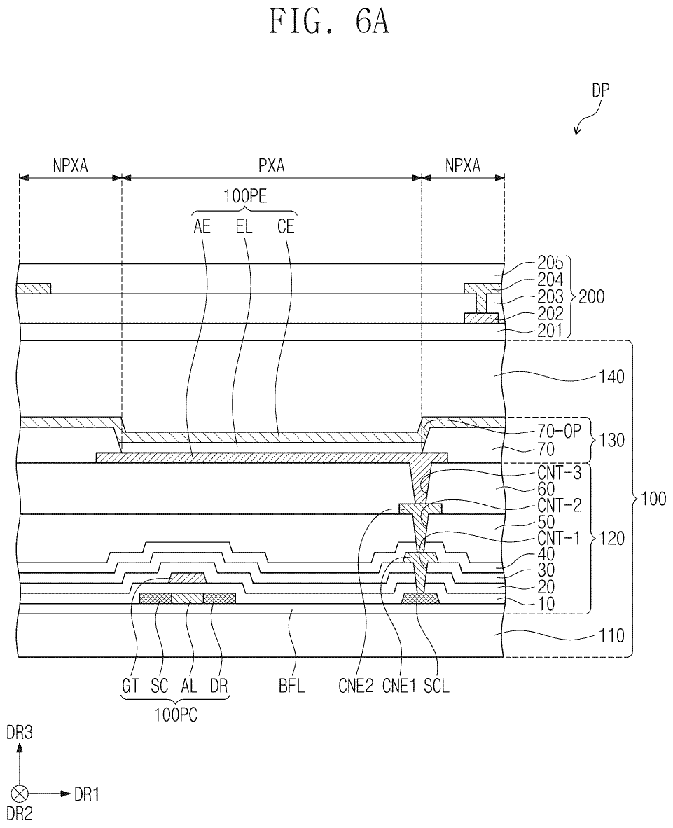

FIG. 5 is a view for describing an operation of the electronic device 1000 according to one or more embodiments of the present disclosure.

Referring to FIG. 5, the electronic device 1000 may include the display layer 100, the sensor layer 200, a display driver 100C, a sensor driver 200C, a main driver 1000C, and a power circuit 1000P.

The sensor layer 200 may sense a first input 2000 or a second input 3000 applied from an external unit. The first input 2000 and the second input 3000 may be input means that may provide a change in a capacitance of the sensor layer 200 or may be input means that may cause an induced current in the sensor layer 200. For example, the first input 2000 may be a passive-type input means such as the human body of the user. The second input 3000 may be an input by the pen PN or an input by a radio frequency integrated circuit (RFIC) tag. For example, the pen PN may be a passive pen or an active pen.

In one or more embodiments of the present disclosure, the pen PN may be a device that generates a magnetic field having a set resonant frequency (e.g., a predetermined resonant frequency). The pen PN may be configured to transmit an output signal based on an electromagnetic resonance method. The pen PN may be referred to as an input device, an input pen, a magnetic pen, a stylus pen, and/or an electromagnetic resonance pen.

The pen PN may include an RLC resonant circuit, and the RLC resonant circuit may include a resistor “R,” an inductor “L,” and a capacitor “C.” In one or more embodiments of the present disclosure, the RLC resonant circuit may be a variable resonant circuit having a variable resonant frequency. In this case, the inductor “L” may be a variable inductor and/or the capacitor “C” may be a variable capacitor, but the present disclosure is not limited thereto.

The inductor “L” generates a current by a magnetic field in (e.g., formed in) the electronic device 1000, for example, the sensor layer 200 or a coil included in the electronic device 1000. However, the present disclosure is not particularly limited thereto. For example, if (e.g., when) the pen PN operates as an active type, the pen PN may also generate a current internally by itself even if (e.g., when) a magnetic field is not provided from the outside. The generated current is transmitted to the capacitor “C.” The capacitor “C” charges a current input from the inductor “L” and discharges the charged current to the inductor “L.” Thereafter, the inductor “L” may emit a magnetic field having a resonant frequency. The induced current may flow in the sensor layer 200 by the magnetic field emitted by the pen PN, and the induced current may be transmitted to the sensor driver 200C as a reception signal (or a sensing signal).

The main driver 1000C may control an overall operation of the electronic device 1000. For example, the main driver 1000C may control operations of the display driver 100C and the sensor driver 200C. The main driver 1000C may include at least one microprocessor and may further include a graphic controller. The main driver 1000C may be referred to as an application processor, a central processing unit, and/or a main processor.

The display driver 100C may drive the display layer 100. The display driver 100C may receive image data and a control signal from the main driver 1000C. The control signal may include one or more suitable signals. For example, the control signal may include an input vertical synchronization signal, an input horizontal synchronization signal, a main clock signal, a data enable signal, and/or the like.

The sensor driver 200C may drive the sensor layer 200. The sensor driver 200C may receive the control signal from the main driver 1000C. The control signal may include a clock signal of the sensor driver 200C. Further, the control signal may further include a mode determining signal that determines driving modes of the sensor driver 200C and the sensor layer 200.

The sensor driver 200C may be implemented as an integrated circuit (IC) and electrically connected to the sensor layer 200. For example, the sensor driver 200C may be directly mounted on a set area (e.g., a predetermined area) of the display panel or mounted on a separate printed circuit board utilizing a chip on film (COF) method and electrically connected to the sensor layer 200.

The sensor driver 200C and the sensor layer 200 may be selectively operated in a first mode or a second mode. For example, the first mode may be a mode for sensing a touch input, for example, the first input 2000. The second mode may be a mode for sensing the input by the pen PN, for example, the second input 3000. The first mode may be referred to as a touch sensing mode, and the second mode may be referred to as a pen-sensing mode.

Switching between the first mode and the second mode may be performed in one or more suitable manners. For example, the sensor driver 200C and the sensor layer 200 may be driven in the first mode and the second mode in a time division manner and may sense the first input 2000 and the second input 3000. Alternatively, the switching between the first mode and the second mode may be generated by selection by the user or by a specific action (or an input) of the user, the first mode or the second mode may be activated or deactivated by activating or deactivating a specific application, or a current mode may be switched from one to the other one of the first mode or the second mode. Alternatively, while the sensor driver 200C and the sensor layer 200 are operated alternately in the first mode and the second mode, if (e.g., when) the first input 2000 is sensed, the first mode may be maintained, or if (e.g., when) the second input 3000 is sensed, the second mode may be maintained.

The sensor driver 200C may calculate coordinate information of the input based on a signal received from the sensor layer 200 and provide a coordinate signal having the coordinate information to the main driver 1000C. The main driver 1000C executes an operation corresponding to the input of the user based on the coordinate signal. For example, the main driver 1000C may operate the display driver 100C, so that a new application image is displayed on the display layer 100.

The power circuit 1000P may include a power management integrated circuit (PMIC). The power circuit 1000P may generate a plurality of driving voltages for driving the display layer 100, the sensor layer 200, the display driver 100C, and/or the sensor driver 200C. For example, the plurality of driving voltages may include a gate-high voltage, a gate-low voltage, a first driving voltage (e.g., an ELVSS voltage), a second driving voltage (e.g., an ELVDD voltage), an initialization voltage, and/or the like, but the present disclosure is not particularly limited to the above example.

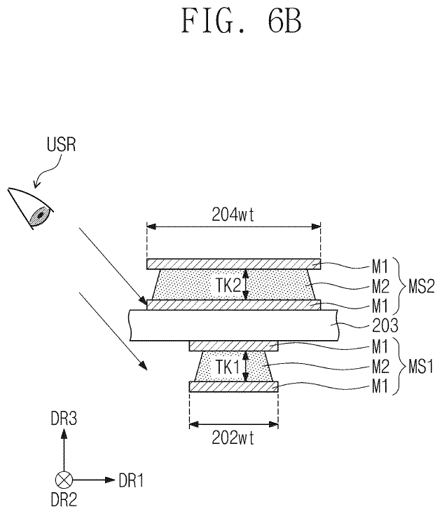

FIG. 6A is a cross-sectional view of the display panel DP according to one or more embodiments of the present disclosure.

Referring to FIG. 6A, at least one buffer layer BFL is provided on an upper surface of the base layer 110. The buffer layer BFL may improve a coupling force between the base layer 110 and the semiconductor pattern. The buffer layer BFL may be provided in multiple layers. Alternatively, the display layer 100 may further include a barrier layer. The buffer layer BFL may include at least one of a silicon oxide, a silicon nitride, and/or a silicon oxy nitride. For example, the buffer layer BFL may include a structure in which silicon oxide layers and silicon nitride layers are alternately laminated.

Semiconductor patterns SC, AL, DR, and SCL may be arranged on the buffer layer BFL. The semiconductor patterns SC, AL, DR, and SCL may include polysilicon. However, the present disclosure is not limited thereto, and the semiconductor patterns SC, AL, DR, and SCL may also include an amorphous silicon, a low-temperature polycrystalline silicon, and/or an oxide semiconductor.

FIG. 6A illustrates some of the semiconductor patterns SC, AL, DR, and SCL, and the semiconductor pattern may be arranged in other areas. The semiconductor patterns SC, AL, DR, and SCL may be arranged in a specific rule across pixels. The semiconductor patterns SC, AL, DR, and SCL may have different electrical properties depending on whether or not the semiconductor patterns SC, AL, DR, and SCL are doped. The semiconductor patterns SC, AL, DR, and SCL may include the first areas defined by the semiconductor patterns SC, DR, and SCL having high conductivity and the second area defined by the semiconductor pattern AL having low conductivity. The first areas defined by the semiconductor patterns SC, DR, and SCL may be doped with an N-type dopant or a P-type dopant. A P-type transistor may include a doped area doped with the P-type dopant, and an N-type transistor may include a doped area doped with the N-type dopant. The second area defined by the semiconductor pattern AL may be a non-doped area or an area doped at a lower concentration than the first areas defined by the semiconductor patterns SC, DR, and SCL.

A conductivity of the first areas defined by the semiconductor patterns SC, DR, and SCL may be greater than a conductivity of the second area defined by the semiconductor pattern AL, and the first areas defined by the semiconductor patterns SC, DR, and SCL may substantially serve as an electrode or a signal line. The second area defined by the semiconductor pattern AL may substantially correspond to an active area or a channel (e.g., a part of the semiconductor pattern AL) of a transistor 100PC. In other words, the part of the semiconductor pattern AL of the semiconductor patterns SC, AL, DR, and SCL may be the active area of the transistor 100PC, the other parts of the semiconductor patterns SC and DR may be the source area or the drain area of the transistor 100PC, and the other part of the semiconductor pattern SCL may be a connection electrode or a connection signal line.

Each of pixels may have an equivalent circuit including a plurality of transistors, at least one capacitor, and at least one light-emitting element, and the equivalent circuit of the pixel may be modified into one or more suitable forms. FIG. 6A illustratively illustrates the one transistor 100PC and one light-emitting element 100PE included in the pixel.

The source area (e.g., the part of the semiconductor pattern SC), the active area (e.g., the part of the semiconductor pattern AL), and the drain area (e.g., the part of the semiconductor pattern DR) of the transistor 100PC may be defined by (e.g., formed from) the semiconductor patterns SC, AL, DR, and SCL. The source area and the drain area may extend from the active area in opposite directions on a cross section. FIG. 6A illustrates a portion of the connection signal line defined by (e.g., formed from) the semiconductor patterns SC, AL, DR, and SCL. Although not separately illustrated, the connection signal line may be connected to the drain area of the transistor 100PC on a plane.

A first insulating layer 10 may be provided on the buffer layer BFL. The first insulating layer 10 may commonly overlap the plurality of pixels and cover the semiconductor patterns SC, AL, DR, and SCL. The first insulating layer 10 may be an inorganic layer and/or an organic layer and may have a single-layer structure or a multi-layer structure. The first insulating layer 10 may include at least one of an aluminum oxide, a titanium oxide, a silicon oxide, a silicon nitride, a silicon oxy nitride, a zirconium oxide, and/or a hafnium oxide. In some embodiments, the first insulating layer 10 may be a single-layer silicon oxide layer. The first insulating layer 10 and an insulating layer of the circuit layer 120, which will be described below, may be an inorganic layer and/or an organic layer and may have a single-layer structure or a multi-layer structure. The inorganic layer may include at least one of the above-described materials, but the present disclosure is not limited thereto.

A gate GT of the transistor 100PC is provided on the first insulating layer 10. The gate GT may be a portion of a metal pattern. The gate GT overlaps the active area of the transistor 100PC. In a process of doping or reducing the semiconductor patterns SC, AL, DR, and SCL, the gate GT may function as a mask.

A second insulating layer 20 may be provided on the first insulating layer 10 and cover the gate GT. The second insulating layer 20 may commonly overlap pixels PX. The second insulating layer 20 may be an inorganic layer and/or an organic layer and may have a single-layer structure or a multi-layer structure. The second insulating layer 20 may include at least one of a silicon oxide, a silicon nitride, and/or a silicon oxy nitride. In some embodiments, the second insulating layer 20 may have a multi-layer structure including a silicon oxide layer and a silicon nitride layer.

A third insulating layer 30 may be provided on the second insulating layer 20. The third insulating layer 30 may have a single-layer structure or a multi-layer structure. For example, the third insulating layer 30 may have a multi-layer structure including a silicon oxide layer and a silicon nitride layer.

A first connection electrode CNE1 may be provided on the third insulating layer 30. The first connection electrode CNE1 may be connected to the connection signal line of the transistor 100PC through a contact hole CNT-1 passing through the first insulating layer 10, the second insulating layer 20, and the third insulating layer 30. A fourth insulating layer 40 may be provided on the third insulating layer 30.

The fourth insulating layer 40 may be a single-layer silicon oxide layer. A fifth insulating layer 50 may be provided on the fourth insulating layer 40. The fifth insulating layer 50 may be an organic layer.

A second connection electrode CNE2 may be provided on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 may be provided on the fifth insulating layer 50 to cover the second connection electrode CNE2. The sixth insulating layer 60 may be an organic layer.

The light-emitting element layer 130 may be provided on the circuit layer 120. The light-emitting element layer 130 may include the light-emitting element 100PE. For example, the light-emitting element layer 130 may include an organic light-emitting material, an inorganic light-emitting material, an organic-inorganic light-emitting material, a quantum dot, a quantum rod, a micro-LED, and/or a nano-LED. Hereinafter, it will be described that the light-emitting element 100PE is an organic light-emitting element, but the present disclosure is not particularly limited thereto.

The light-emitting element 100PE may include a first electrode AE, a light-emitting layer EL, and a second electrode CE.

The first electrode AE may be provided on the sixth insulating layer 60. The first electrode AE may be connected to the second connection electrode CNE2 through a contact hole CNT-3 passing through the sixth insulating layer 60.

A pixel defining film 70 may be provided on the sixth insulating layer 60 and cover a portion of the first electrode AE. An opening 70-OP is defined in the pixel defining film 70. The opening 70-OP of the pixel defining film 70 exposes at least a portion of the first electrode AE.

The first display DA1-F (see FIG. 1A) may include a light-emitting area PXA and a non-light-emitting area NPXA adjacent to the light-emitting area PXA. The non-light-emitting area NPXA may surround the light-emitting area PXA. In some embodiments, the light-emitting area PXA may be defined to correspond to a partial area of the first electrode AE, which is exposed by the opening 70-OP.

The light-emitting layer EL may be provided on the first electrode AE. The light-emitting layer EL may be provided in an area corresponding to the opening 70-OP. FIG. 6A illustratively illustrates that the light-emitting layer EL is provided inside the opening 70-OP, but the present disclosure is not limited thereto. For example, the light-emitting layer EL may extend to cover portions of a side surface of the pixel defining film 70 that defines the opening 70-OP and an upper surface of the pixel defining film 70.

In one or more embodiments of the present disclosure, the light-emitting layer EL may be provided (e.g., formed) separately from each of the pixels. If (e.g., when) the light-emitting layer EL is provided separately from each of the pixels, each of the light-emitting layers EL may emit a light having at least one of a blue color, a red color, and/or a green color. However, the present disclosure is not limited thereto, and the light-emitting layer EL may have an integral shape and may be commonly included in the plurality of pixels. In some embodiments, the light-emitting layer EL may also provide a white light.

The second electrode CE may be provided on the light-emitting layer EL. The second electrode CE may have an integral shape and may be commonly included in the plurality of pixels.

In one or more embodiments of the present disclosure, a hole control layer may be provided between the first electrode AE and the light-emitting layer EL. The hole control layer may be commonly provided in the light-emitting area PXA and the non-light-emitting area NPXA. The hole control layer may include a hole transport layer and may further include a hole injection layer. An electron control layer may be provided between the light-emitting layer EL and the second electrode CE. The electron control layer may include an electron transport layer and may further include an electron injection layer. The hole control layer and the electron control layer may be commonly provided in the plurality of pixels by utilizing an open mask or an inkjet process.

The encapsulation layer 140 may be provided on the light-emitting element layer 130. The encapsulation layer 140 may include an inorganic layer, an organic layer, and an inorganic layer that are sequentially laminated, and layers constituting the encapsulation layer 140 are not limited thereto. The inorganic layers may protect the light-emitting element layer 130 from moisture and oxygen, and the organic layer may protect the light-emitting element layer 130 from foreign substances such as dust particles. The inorganic layers may include a silicon nitride layer, a silicon oxy nitride layer, a silicon oxide layer, a titanium oxide layer, an aluminum oxide layer, and/or the like. The organic layer may include an acryl-based organic layer, and the present disclosure is not limited thereto.

The sensor layer 200 may include a base layer 201, a first conductive layer 202, an intermediate insulating layer 203, a second conductive layer 204, and a cover insulating layer 205.

The base layer 201 may be an inorganic layer including at least one of a silicon nitride, a silicon oxy nitride, and/or a silicon oxide. Alternatively, the base layer 201 may be an organic layer including an epoxy resin, an acryl-based resin, and/or an imide-based resin. The base layer 201 may have a single-layer structure or have a multi-layer structure in which layers are laminated in the third direction DR3. In some embodiments of the present disclosure, the sensor layer 200 may not include the base layer 201.

Each of the first conductive layer 202 and the second conductive layer 204 may have a single-layer structure or have a multi-layer structure in which layers are laminated in the third direction DR3.

Each of the first conductive layer 202 and the second conductive layer 204 having a single-layer structure may include a metal layer or a transparent conductive layer. The metal layer may include molybdenum, silver, titanium, copper, aluminum, and/or alloys thereof. The transparent conductive layer may include a transparent conductive oxide such as an indium tin oxide (ITO), an indium zinc oxide (IZO), a zinc oxide (ZnO), and/or an indium zinc tin oxide (IZTO). In addition, the transparent conductive layer may include a conductive polymer, such as poly (3,4-ethylenedioxythiophene) (PEDOT), metal nanowire, graphene, and/or the like.

Each of the first conductive layer 202 and the second conductive layer 204 having a multi-layer structure may include metal layers. The metal layers may have, for example, a three-layer structure of titanium/aluminum/titanium (e.g., a layer of titanium, a layer of aluminum, and a layer of titanium). The conductive layer having a multi-layer structure may include at least one metal layer and at least one transparent conductive layer.

In some embodiments of the present disclosure, a thickness of the first conductive layer 202 may be greater than or equal to a thickness of the second conductive layer 204. If (e.g., when) the thickness of the first conductive layer 202 is greater than the thickness of the second conductive layer 204, a resistance of a component (e.g., an electrode, a sensing pattern, a bridge pattern, and/or the like) included in the first conductive layer 202 may be decreased. Further, because the first conductive layer 202 is provided under the second conductive layer 204, even if (e.g., when) the thickness of the first conductive layer 202 is increased, a probability that components included in the first conductive layer 202 are visible due to reflection of an external light may be smaller than that of the second conductive layer 204.

At least one of the intermediate insulating layer 203 and the cover insulating layer 205 may include an inorganic film. The inorganic film may include at least one of an aluminum oxide, a titanium oxide, a silicon oxide, a silicon nitride, a silicon oxy nitride, a zirconium oxide, and/or a hafnium oxide.

At least one of the intermediate insulating layer 203 or the cover insulating layer 205 may include an organic film. The organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and/or a perylene-based resin.

The fact that the sensor layer 200 includes the first conductive layer 202 and the second conductive layer 204, e.g., a total of two conductive layers, has been described above, but the present disclosure is not particularly limited thereto. For example, the sensor layer 200 may include three or more conductive layers.

FIG. 6B is a cross-sectional view of the sensor layer 200 according to one or more embodiments of the present disclosure.

Referring to FIGS. 6A and 6B, a second width 204wt of a second mesh line MS2 included in the second conductive layer 204 may be greater than or equal to a first width 202wt of a first mesh line MS1 included in the first conductive layer 202. If (e.g., when) a user USR views the first mesh line MS1 and the second mesh line MS2 from a side surface, the first mesh line MS1 has a width that is smaller than that of the second mesh line MS2, and thus a probability that the first mesh line MS1 is visually recognized by the user USR may be decreased.

Each of the first mesh line MS1 and the second mesh line MS2 may include first metal layers M1 and a second metal layer M2 provided between the first metal layers M1. Illustratively, the first metal layers M1 may include titanium (Ti), and the second metal layer M2 may include aluminum (Al). However, this is an example, and the present disclosure is not particularly limited thereto.

In one or more embodiments of the present disclosure, a first thickness TK1 of the second metal layer M2 of the first mesh line MS1 may be substantially the same as a second thickness TK2 of the second metal layer M2 of the second mesh line MS2, but the present disclosure is not particularly limited thereto. For example, the first thickness TK1 may be greater than the second thickness TK2. Alternatively, the second thickness TK2 may be greater than the first thickness TK1. Because the first mesh line MS1 is provided under the second mesh line MS2, even if (e.g., when) the thickness of the first mesh line MS1 is increased, a probability that the first mesh line MS1 is visually recognized due to the reflection of the external light may be lower than that of the second mesh line MS2. In some embodiments of the present disclosure, each of the first thickness TK1 and the second thickness TK2 may be 1,000 Å or more, and for example, 6,000 Å.

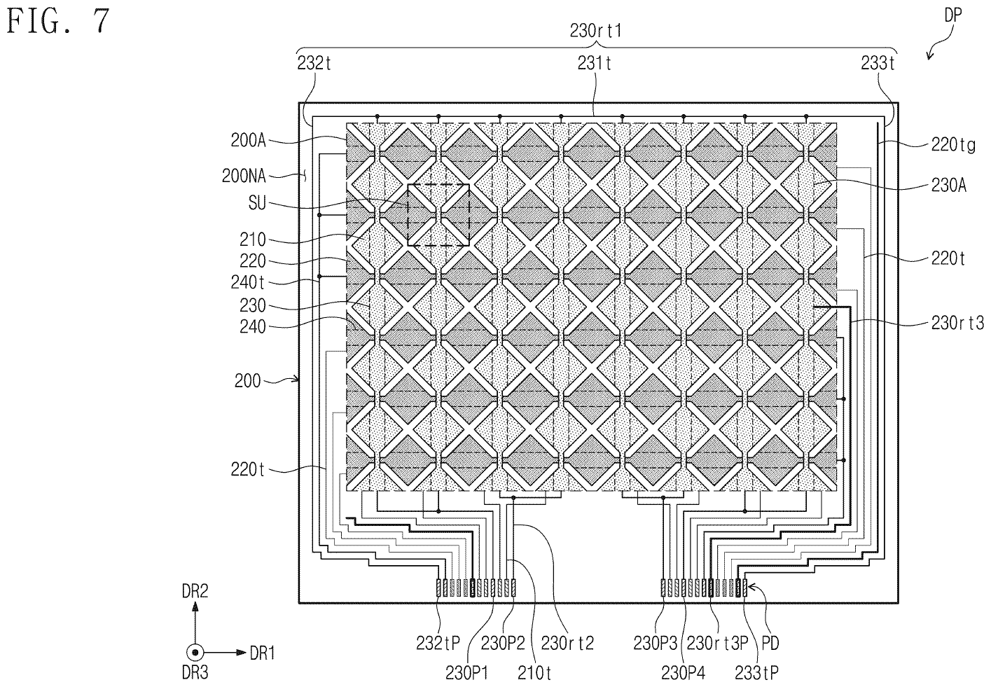

FIG. 7 is a plan view of the display panel DP according to one or more embodiments of the present disclosure.

Referring to FIG. 7, the display panel DP includes the sensor layer 200. The sensing area 200A and the peripheral area 200NA adjacent to the sensing area 200A may be defined in the sensor layer 200. The sensor layer 200 may include a plurality of first electrodes 210, a plurality of second electrodes 220, a plurality of third electrodes 230, and a plurality of fourth electrodes 240, which are arranged in the sensing area 200A.

The first electrodes 210 may cross the second electrodes 220. Each of the first electrodes 210 may extend in the second direction DR2, and the first electrodes 210 may be arranged to be separated from (e.g., spaced apart from) each other in the first direction DR1. Each of the second electrodes 220 may extend in the first direction DR1, and the second electrodes 220 may be arranged to be separated from (e.g., spaced apart from) each other in the second direction DR2. A sensing unit (e.g., a sensing node or a sensor) SU of the sensor layer 200 may include an area in which the one first electrode 210 and the one second electrode 220 cross each other.

FIG. 7 illustratively illustrates eight first electrodes 210 and six second electrodes 220 and illustratively illustrates 48 sensing units SU, but the number of first electrodes 210 and the number of second electrodes 220 are not limited thereto.

According to one or more embodiments of the present disclosure, a width of the sensing area 200A in the first direction DR1 may be greater than or equal to a width of the sensing area 200A in the second direction DR2. Thus, the number of first electrodes 210 arranged in the first direction DR1 may be greater than the number of second electrodes 220 arranged in the second direction DR2. However, the present disclosure is not limited thereto, and the width of the sensing area 200A in the second direction DR2 may be greater than or equal to the width of the sensing area 200A in the first direction DR1. In this case, the number of first electrodes 210 arranged in the first direction DR1 may be smaller than the number of second electrodes 220 arranged in the second direction DR2.

Each of the third electrodes 230 may extend in the second direction DR2, and the third electrodes 230 may be arranged to be separated from (e.g., spaced apart from) each other in the first direction DR1. The one third electrode 230 may overlap the one first electrode 210. In the specification, the wording “A and B overlap each other” may mean that a portion of “A” and a portion of “B” overlap each other, mean that the entirety of “A” and a portion of “B” overlap each other, mean that the entirety of “B” and a portion of “A” overlap each other, or mean that the entirety of “A” and the entirety of “B” overlap each other.

According to one or more embodiments of the present disclosure, an overlapping area between the one first electrode 210 and the one third electrode 230 may be adjusted to adjust a capacitance (or a coupling capacitance) between the one first electrode 210 and the one third electrode 230. The third electrodes 230 may also be referred to as first auxiliary electrodes or charging electrodes.

The fourth electrodes 240 may be arranged in the second direction DR2, and the fourth electrodes 240 may extend in the first direction DR1. The one fourth electrode 240 may at least partially overlap the one second electrode 220.

According to one or more embodiments of the present disclosure, an overlapping area between the one second electrode 220 and the one fourth electrode 240 may be adjusted to adjust a capacitance (or a coupling capacitance) between the one second electrode 220 and the one fourth electrode 240. The fourth electrodes 240 may also be referred to as second auxiliary electrodes or sensing auxiliary electrodes.

In one or more embodiments of the present disclosure, both ends of at least some of the third electrodes 230 may be electrically connected to each other to constitute one first electrode group. For example, FIG. 7 illustratively illustrates that both ends of the two third electrodes 230 are electrically connected to each other to constitute the one first electrode group. However, the present disclosure is not particularly limited thereto. For example, the one first electrode group may include only the one third electrode or three or more third electrodes. As the number of third electrodes 230 connected in parallel and included in the one first electrode group is increased, resistance of the one first electrode group is decreased, and thus power efficiency may be improved, and sensing sensitivity may be improved. In contrast, as the number of third electrodes 230 included in the one first electrode group is decreased, a coil pattern provided utilizing the one first electrode group may be implemented in more suitable forms.

In one or more embodiments of the present disclosure, at least some of the fourth electrodes 240 may be electrically connected to each other to constitute one second electrode group. For example, FIG. 7 illustratively illustrates that the three fourth electrodes 240 are connected to the same trace line, for example, an auxiliary trace line 240t, to constitute the one second electrode group. Thus, FIG. 7 illustrates that the two second electrode groups are arranged in the second direction DR2. However, the number of fourth electrodes 240 constituting the one second electrode group is not limited thereto. For example, the number of fourth electrodes 240 constituting the one second electrode group may be six, and in this case, the sensor layer 200 may include the one second electrode group.

The sensor layer 200 may further include a plurality of first trace lines 210t and a plurality of second trace lines 220t arranged in the peripheral area 200NA. The first trace lines 210t and the second trace lines 220t may be arranged to overlap the non-display area 100NA of the display layer 100 (see FIG. 4). The first trace lines 210t may be electrically connected to the first electrodes 210 in one-to-one correspondence. The second trace lines 220t may be electrically connected to the second electrodes 220 in one-to-one correspondence. Some of the second trace lines 220t and the other second trace lines 220t may be separated from (e.g., spaced apart from) each other with the sensing area 200A interposed therebetween.

The sensor layer 200 may further include a first loop trace line 230rt1, a plurality of second loop trace lines 230rt2, a third loop trace line 230rt3, and the auxiliary trace lines 240t.

In one or more embodiments of the present disclosure, the first loop trace line 230rt1 may be electrically connected to all the third electrodes 230. For example, ends of the third electrodes 230 may be connected to the first loop trace line 230rt1. The first loop trace line 230rt1 may include a first line portion 231t extending in the first direction DR1 and electrically connected to the third electrodes 230, a second line portion 232t extending parallel to the second direction DR2 from a first end of the first line portion 231t, and a third line portion 233t extending parallel to the second direction DR2 from a second end of the first line portion 231t.

In one or more embodiments of the present disclosure, the first loop trace line 230rt1 may have a shape surrounding at least a portion of the sensing area 200A. The second line portion 232t and the third line portion 233t may be separated from (e.g., spaced apart from) each other with the sensing area 200A interposed therebetween and arranged in the peripheral area 200NA. In a charging drive mode, a signal may be provided to at least one of the second line portion 232t or the third line portion 233t. For example, the first line portion 231t of the first loop trace line 230rt1 may function as a shorting bar that electrically connects all the third electrodes 230, and the second line portion 232t and the third line portion 233t of the first loop trace line 230rt1 may function as the third electrode 230 in the peripheral area 200NA. Thus, the pen PN (see FIG. 5) positioned in an area adjacent to the peripheral area 200NA may also be sufficiently charged by a current loop including the second line portion 232t or the third line portion 233t.

In one or more embodiments of the present disclosure, the first loop trace line 230rt1 may include only the first line portion 231t and may not include the second line portion 232t and the third line portion 233t. In this case, the first loop trace line 230rt1 may function as a shorting bar that electrically connects all the third electrodes 230.

In one or more embodiments of the present disclosure, the second loop trace lines 230rt2 may be electrically connected to the third electrodes 230. For example, the one second loop trace line 230rt2 may be electrically connected to the one first electrode group described above. For example, FIG. 7 illustratively illustrates four first electrode groups. Each of the first electrode groups may include the two third electrodes 230. Thus, the four second loop trace lines 230rt2 may be provided.

In one or more embodiments of the present disclosure, the third loop trace line 230rt3 may be electrically connected to one third electrode 230A among the third electrodes 230. The one third electrode 230A among the third electrodes 230 may be closest to the peripheral area 200NA. FIG. 7 illustratively illustrates that the one third electrode 230 is an electrode provided on a rightmost side in the sensing area 200A, but the present disclosure is not particularly limited thereto. For example, the one third electrode 230 may be an electrode provided on a leftmost side in the sensing area 200A.

The one third electrode 230 may be electrically connected to all the first loop trace line 230rt1, the one second loop trace line 230rt2, and the third loop trace line 230rt3.

According to one or more embodiments of the present disclosure, in the charging drive mode, a signal may also be provided to the third loop trace line 230rt3. For example, a magnetic field may be additionally provided in the peripheral area 200NA by the third loop trace line 230rt3 and the one third electrode 230 electrically connected to the third loop trace line 230rt3. Thus, the pen positioned adjacent to the peripheral area 200NA may also be sufficiently charged by a current loop including the third loop trace line 230rt3. In this case, as the sensor layer 200 is applied to a medium to large-sized electronic device such as a tablet or a monitor, even if (e.g., when) an area of the peripheral area 200NA is increased, the pen PN (see FIG. 5) may be sufficiently charged in a space adjacent to the peripheral area 200NA by additionally utilizing the third loop trace line 230rt3. Thus, pen charging performance of the electronic device 1000 (see FIG. 1A) may be improved.

The first loop trace line 230rt1 may be connected to one end of the one third electrode 230, and the one second loop trace line 230rt2 may be connected to the other end of the one third electrode 230. The third loop trace line 230rt3 may be connected to an area between the one end and the other end of the one third electrode 230.

FIG. 7 illustratively illustrates that the third loop trace line 230rt3 is connected to an area adjacent to a middle point of the one third electrode 230, but the present disclosure is not particularly limited thereto. For example, the third loop trace line 230rt3 may also be connected in an upper area adjacent to the one end of the one third electrode 230 or may also be connected to a lower area adjacent to the other end of the one third electrode 230. The upper area and the lower area mean an upper area and a lower area on a plane defined by the first direction DR1 and the second direction DR2. The auxiliary trace lines 240t may be separated from (e.g., spaced apart from) each other with the sensing area 200A interposed therebetween. FIG. 7 illustratively illustrates that two second electrode groups are arranged. The auxiliary trace line 240t connected to the three fourth electrodes 240 arranged on the upper side and the auxiliary trace line 240t connected to the three fourth electrodes 240 arranged on the lower side may be separated from (e.g., spaced apart from) each other with the sensing area 200A interposed therebetween. However, the present disclosure is not particularly limited thereto.

The sensor layer 200 may further include a plurality of guard lines 200tg arranged in the peripheral area 200NA. According to an operation mode of the sensor layer 200, the guard lines 200tg may be grounded or floating or a set signal (e.g., a predetermined signal) may be applied. For example, if (e.g., when) the sensor layer 200 is operated in a mutual capacitance detecting mode or a pen-sensing drive mode, the guard lines 200tg may be grounded.

If (e.g., when) the sensor layer 200 is driven in a self-capacitance detecting mode, the same signal as the signal provided to adjacent trace lines may be provided to the guard lines 200tg. Thus, a parasitic capacitance provided between trace lines may be reduced or removed by the guard lines 200tg. If (e.g., when) the sensor layer 200 is operated in a pen charging drive mode, the guard lines 200tg may be floating. The floating may mean a state in which a signal is not provided to a pad connected to the guard lines 200tg.

The sensor layer 200 may further include a plurality of pads PD arranged in the peripheral area 200NA. FIG. 7 illustratively illustrates that the pads PD are arranged in one row in the first direction DR1, but the present disclosure is not limited thereto. For example, the pads PD may be arranged in a plurality of rows. The pads PD may be electrically connected to the first trace lines 210t, the second trace lines 220t, both ends of the first loop trace lines 230rt1, the second loop trace lines 230rt2, the third loop trace line 230rt3, the auxiliary trace lines 240t, and the guard lines 200tg, which are described above, in one-to-one correspondence.

The pads PD may include charging driving pads 232tP, 230P1, 230P2, 230P3, 230P4, 230rt3P, and 233tP. The charging driving pads 232tP, 230P1, 230P2, 230P3, 230P4, 230rt3P, and 233tP may be electrically connected to both ends of the first loop trace lines 230rt1, the second loop trace lines 230rt2, and the third loop trace line 230rt3 in one-to-one correspondence.

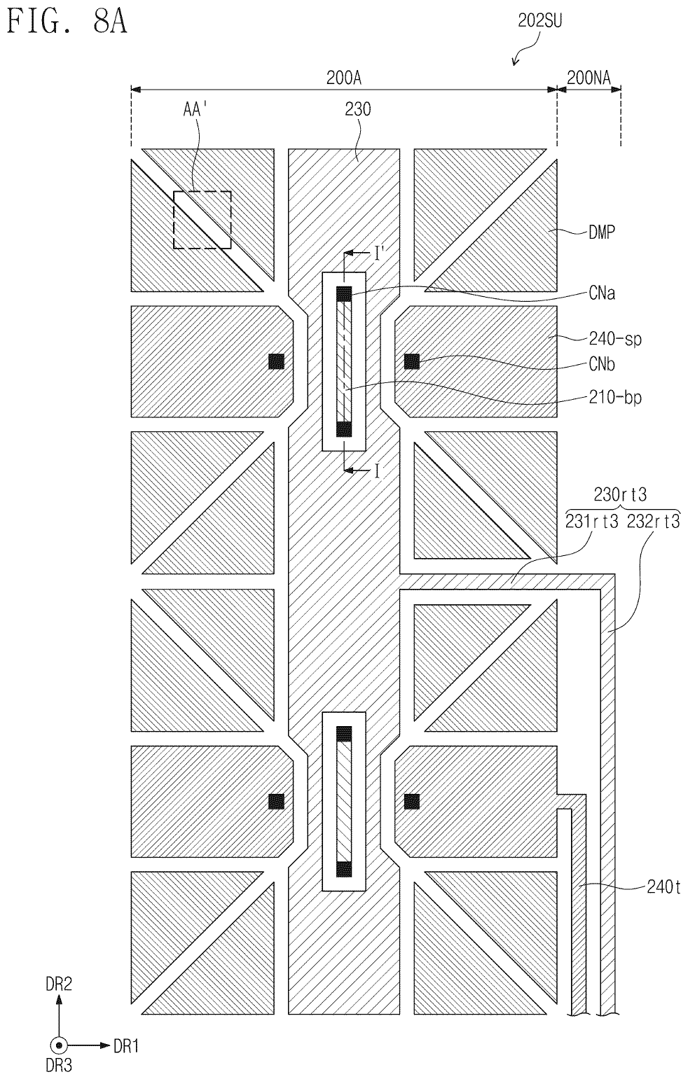

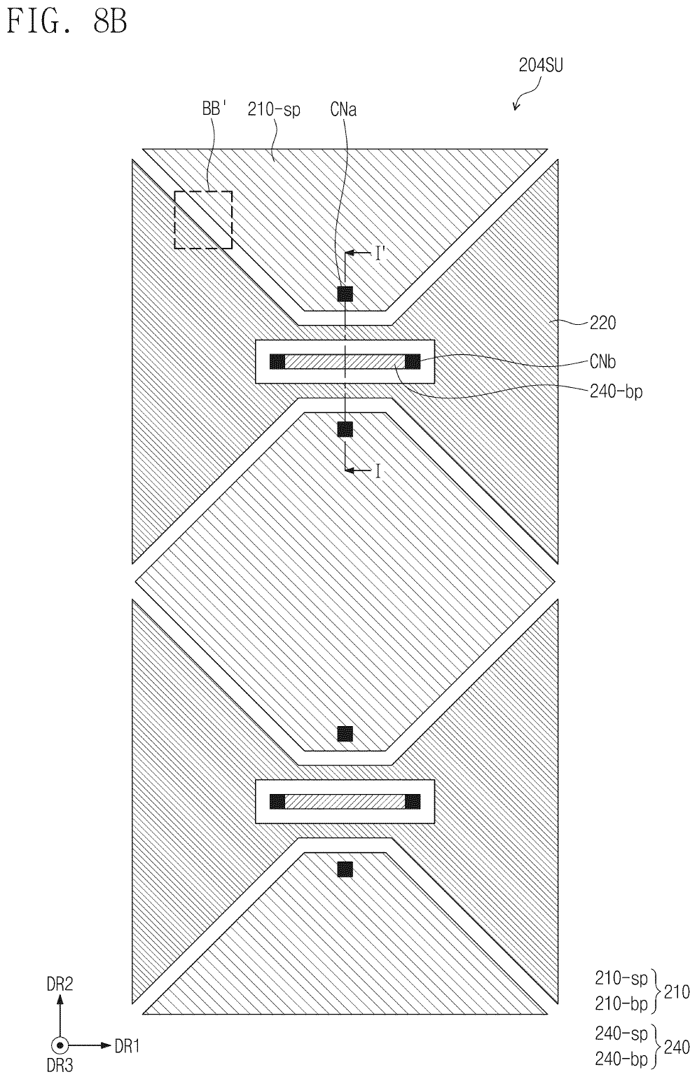

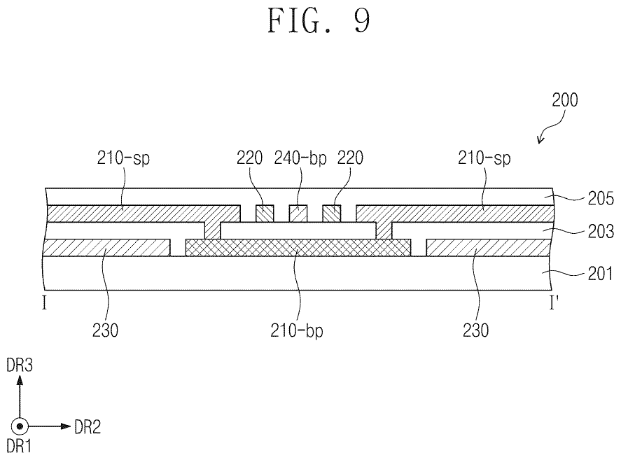

FIG. 8A is a plan view illustrating a first conductive layer of two sensors according to one or more embodiments of the present disclosure. FIG. 8B is a plan view illustrating a second conductive layer of the two sensors according to one or more embodiments of the present disclosure. FIG. 9 is a cross-sectional view of the sensor layer along the line I-l′ illustrated in FIGS. 8A and 8B according to one or more embodiments of the present disclosure.

FIGS. 8A and 8B illustratively illustrate shapes of a first conductive layer 202SU and a second conductive layer 204SU of the two sensors adjacent to the peripheral area 200NA. However, the illustrated shapes are merely an example, and the shapes of the first conductive layer 202SU and the second conductive layer 204SU are not limited thereto.

Referring to FIGS. 8A and 8B, a portion of the one first electrode 210, portions of the two second electrodes 220, a portion of the one third electrode 230, and portions of the two fourth electrodes 240 are illustrated.

According to one or more embodiments of the present disclosure, the first electrode 210 may include first patterns 210-sp and a first bridge pattern 210-bp. The first patterns 210-sp and the first bridge pattern 210-bp may be electrically connected to each other through a first contact CNa. The second electrode 220 may be provided on the same layer as the first patterns 210-sp. For example, the first patterns 210-sp may be separated from (e.g., spaced apart from) each other with the second electrode 220 interposed therebetween. The first bridge pattern 210-bp may be provided on a different layer from the second electrode 220 and may be insulated from and cross the second electrode 220.

The third electrode 230 may be provided on the same layer as the first bridge pattern 210-bp. An opening surrounding the first bridge pattern 210-bp may be defined in the third electrode 230. The third electrode 230 may overlap the first patterns 210-sp. Thus, a coupling capacitor may be defined between the first electrode 210 and the third electrode 230.

FIG. 8A illustratively illustrates that the one first bridge pattern 210-bp is provided in the one opening defined in the third electrode 230, but the present disclosure is not particularly limited thereto. For example, the two first bridge patterns 210-bp may be arranged in the one opening, and in this case, the two first patterns 210-sp adjacent to each other may be electrically connected to each other by the two first bridge patterns 210-bp.

The fourth electrode 240 may include second patterns 240-sp and a second bridge pattern 240-bp. The second patterns 240-sp and the second bridge pattern 240-bp may be electrically connected to each other through a second contact CNb. The third electrode 230 may be provided on the same layer as the second patterns 240-sp. For example, the second patterns 240-sp may be separated from (e.g., spaced apart from) each other with the third electrode 230 interposed therebetween. The second bridge pattern 240-bp may be provided on a different layer from the third electrode 230 and may be insulated from and cross the third electrode 230.

In one or more embodiments of the present disclosure, the first conductive layer 202SU may include the first bridge pattern 210-bp, the third electrode 230, and the second patterns 240-sp. The second conductive layer 204SU may include the first patterns 210-sp, the second electrode 220, and the second bridge pattern 240-bp.

Referring to FIG. 8A, the third loop trace line 230rt3 and the auxiliary trace line 240t are illustratively illustrated. Referring to FIGS. 7 and 8A, the third electrode 230 illustrated in FIG. 8A may be the one third electrode 230A. Thus, the third loop trace line 230rt3 may be connected to the one third electrode 230A.

The third loop trace line 230rt3 may include a first portion 231rt3 provided in the sensing area 200A and a second portion 232rt3 provided in the peripheral area 200NA. The first portion 231rt3 may extend in the first direction DR1, and the second portion 232rt3 may extend in the second direction DR2. The first portion 231rt3 may overlap the first electrode 210. For example, the first portion 231rt3 may overlap the first pattern 210-sp included in the second conductive layer 204SU.

Referring to FIGS. 7 and 8A, the second portion 232rt3 of the third loop trace line 230rt3 may be provided between the sensing area 200A and the third line portion 233t of the first loop trace line 230rt1. Further, the second portion 232rt3 of the third loop trace line 230rt3 may be provided between the auxiliary trace line 240t and at least some of the second trace lines 220t. Depending on the position of the third loop trace line 230rt3, the third loop trace line 230rt3 may also be provided between the second trace lines 220t.

According to one or more embodiments of the present disclosure, the width of the sensing area 200A in the first direction DR1 may be greater than the width of the sensing area 200A in the second direction DR2, and the third loop trace line 230rt3 may be separated from (e.g., spaced apart from) the sensing area 200A in the first direction DR1. A magnetic field may be additionally provided in the peripheral area 200NA by the third loop trace line 230rt3 and the one third electrode 230 electrically connected to the third loop trace line 230rt3. Thus, the pen PN (see FIG. 5) positioned adjacent to the peripheral area 200NA may also be sufficiently charged by the current loop including the third loop trace line 230rt3.

In one or more embodiments of the present disclosure, the first conductive layer 202SU may further include dummy patterns DMP. Because the dummy patterns DMP are arranged in an empty space, a probability that specific patterns are visually recognized by reflection of an external light may be decreased. For example, the electronic device 1000 (see FIG. 1A) having improved visibility due to the reflection of the external light may be provided. Each of the dummy patterns DMP may be electrically floating or electrically grounded. In one or more embodiments of the present disclosure, the dummy patterns DMP may be omitted.

Referring to FIGS. 7, 8A, and 8B, in the second conductive layer 204SU inside the one sensing unit SU, an area occupied by components included in the first electrode 210 and the second electrode 220 may be greater than an area occupied by components included in the third electrode 230 and the fourth electrode 240. A change in the capacitance due to the first input 2000 (see FIG. 4) may be greater as a distance therefrom becomes shorter. Thus, components for sensing the first input 2000 (see FIG. 4) may be arranged in a relatively larger area in a layer adjacent to a surface of the electronic device 1000 (see FIG. 1A). As a result, touch performance may be improved.

Hereinabove, FIGS. 6A to 9 illustratively illustrates a structure in which the first to fourth electrodes 210, 220, 230, and 240 are divided and arranged into the two conductive layers 202SU and 204SU, but the present disclosure is not particularly limited thereto. For example, the first to fourth electrodes 210, 220, 230, and 240 may be divided and arranged into three conductive layers or four conductive layers.

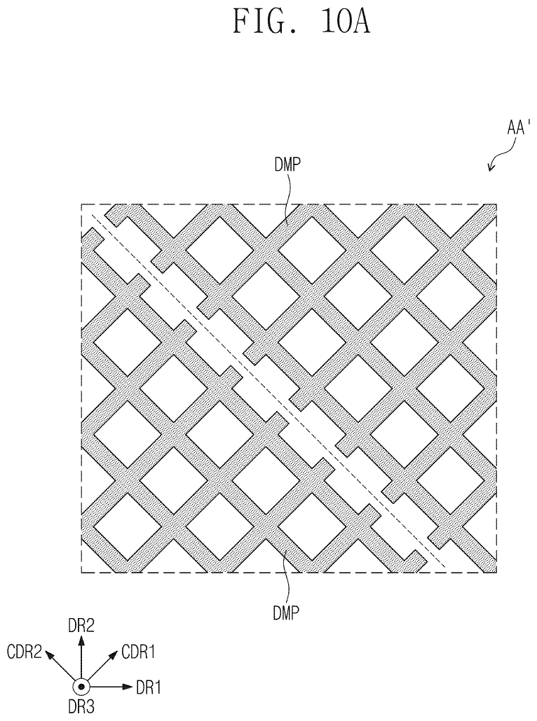

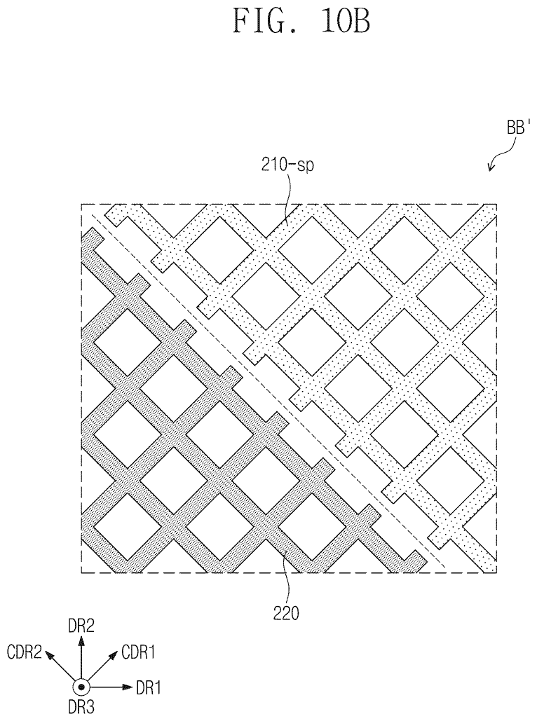

FIG. 10A is an enlarged plan view of area AA′ illustrated in FIG. 8A. FIG. 10B is an enlarged plan view of area BB′ illustrated in FIG. 8B.

Referring to FIGS. 8A, 8B, 10A, and 10B, each of the first electrodes 210, the second electrodes 220, the third electrodes 230, the fourth electrodes 240, and the dummy patterns DMP may have a mesh structure. Each of the mesh structures may include a plurality of mesh lines. Each of the plurality of mesh lines may have a shape extending in a set direction (e.g., a predetermined direction), and the mesh lines may be connected to each other. The shape may be one or more suitable shapes such as a straight line, a line having a protrusion, and an uneven line. Openings not having a mesh structure may be defined (provided or formed) in each of the first electrodes 210, the second electrodes 220, the third electrodes 230, the fourth electrodes 240, and the dummy patterns DMP.

FIGS. 10A and 10B illustratively illustrate that the mesh structure includes mesh lines extending in a first intersection direction CDR1 that intersects the first direction DR1 and the second direction DR2 and mesh lines extending in a second intersection direction CDR2 that intersects the first intersection direction CDR1. However, the extension directions of the mesh lines constituting the mesh structure are not particularly limited to illustration of FIGS. 10A and 10B. For example, the mesh structure may include only mesh lines extending in the first direction DR1 and the second direction DR2 or may include mesh lines extending in the first direction DR1, the second direction DR2, the first intersection direction CDR1, and the second intersection direction CDR2. In some embodiments, the mesh structure may be changed into one or more suitable forms.

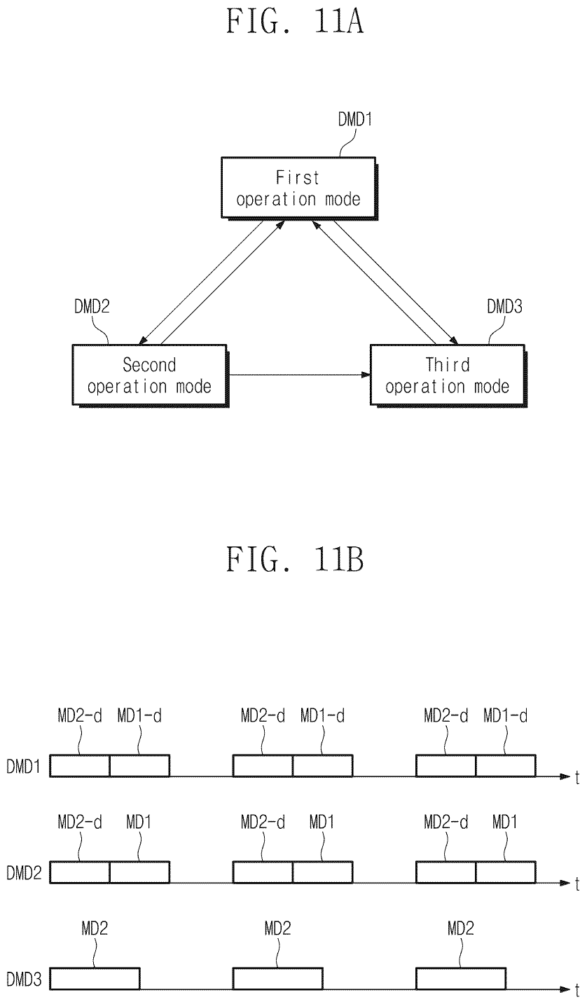

FIG. 11A is a view illustrating an operation of the sensor driver 200C (see FIG. 5) according to one or more embodiments of the present disclosure.

Referring to FIGS. 5 and 11A, the sensor driver 200C may be selectively driven in one of a first operation mode DMD1, a second operation mode DMD2, or a third operation mode DMD3.

The first operation mode DMD1 may be referred to as a touch and pen waiting mode, the second operation mode DMD2 may be referred to as a touch activation and pen waiting mode, and the third operation mode DMD3 may be referred to as a pen activation mode. The first operation mode DMD1 may be a mode that waits for the first input 2000 and the second input 3000. The second operation mode DMD2 may be a mode that senses the first input 2000 and waits for the second input 3000. The third operation mode DMD3 may be a mode that senses the second input 3000.

In one or more embodiments of the present disclosure, the sensor driver 200C may be first driven in the first operation mode DMD1. If (e.g., when) the first input 2000 is sensed in the first operation mode DMD1, the sensor driver 200C may be switched (or changed) to the second operation mode DMD2. Alternatively, if (e.g., when) the second input 3000 is sensed in the first operation mode DMD1, the sensor driver 200C may be switched (or changed) to the third operation mode DMD3.

In one or more embodiments of the present disclosure, if (e.g., when) the second input 3000 is sensed in the second operation mode DMD2, the sensor driver 200C may be switched to the third operation mode DMD3. If (e.g., when) the first input 2000 is released (or not sensed) in the second operation mode DMD2, the sensor driver 200C may be switched to the first operation mode DMD1. If (e.g., when) the second input 3000 is released (or not sensed) in the third operation mode DMD3, the sensor driver 200C may be switched to the first operation mode DMD1.

FIG. 11B is a view illustrating the operation of the sensor driver 200C according to one or more embodiments of the present disclosure.

Referring to FIGS. 5, 11A, and 11B, operations in the first to third operation modes DMD1, DMD2, and DMD3 are illustratively illustrated in order of time “t.”

In the first operation mode DMD1, the sensor driver 200C may be repeatedly driven in a second mode MD2-dand a first mode MD1-d. During the second mode MD2-d, the sensor layer 200 may be scan-driven to detect the second input 3000. During the first mode MD1-d, the sensor layer 200 may be scan-driven to detect the first input 2000. FIG. 11B illustratively illustrates that the sensor driver 200C is operated in the first mode MD1-d continuously after the second mode MD2-d, but a sequence thereof is not limited thereto.

In the second operation mode DMD2, the sensor driver 200C may be repeatedly driven in the second mode MD2-d and a first mode MD1. During the second mode MD2-d, the sensor layer 200 may be scan-driven to detect the second input 3000. During the first mode MD1, the sensor layer 200 may be scan-driven to detect coordinates by the first input 2000.

In the third operation mode DMD3, the sensor driver 200C may be driven in a second mode MD2. During the second mode MD2, the sensor layer 200 may be scan-driven to detect coordinates by the second input 3000. In the third operation mode DMD3, the sensor driver 200C may not be operated in the first mode MD1-d or MD1 until the second input 3000 is released (or not sensed).

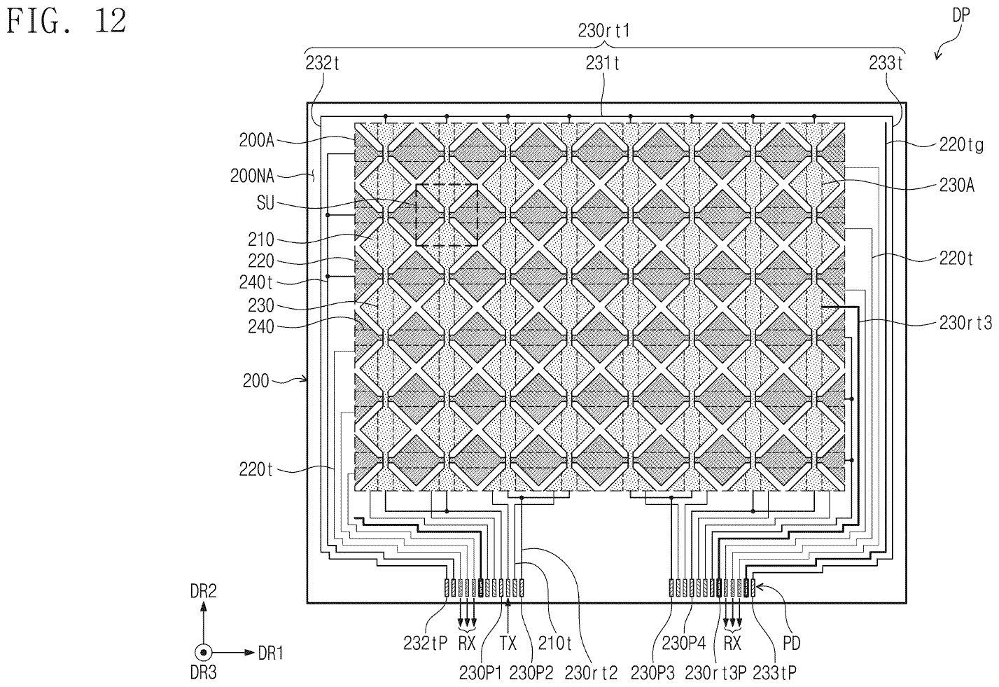

FIG. 12 is a view for describing a first mode according to one or more embodiments of the present disclosure.

Referring to FIGS. 5, 11B, and 12, the first mode MD1-d of the first operation mode DMD1 and the first mode MD1 of the second operation mode DMD2 may include a mutual capacitance detecting mode. FIG. 12 is a view for describing the mutual capacitance detecting mode in the first mode MD1-d of the first operation mode DMD1 and the first mode MD1 of the second operation mode DMD2.

In the mutual capacitance detecting mode, the sensor driver 200C may sequentially provide a transmission signal TX to the first electrodes 210 and detect coordinates for the first input 2000 utilizing a reception signal RX detected through the second electrodes 220. For example, the sensor driver 200C may calculate input coordinates by sensing a change in a mutual capacitance between the first electrodes 210 and the second electrodes 220.

FIG. 12 illustratively expresses that the transmission signal TX is provided to the one first electrode 210 and the reception signal RX is output from the second electrodes 220. The sensor driver 200C may detect input coordinates for the first input 2000 by sensing the change in the capacitance between the first electrodes 210 and the second electrodes 220.

In the first mode MD1-d of the first operation mode DMD1 and the first mode MD1 of the second operation mode DMD2, all the third electrodes 230, the fourth electrodes 240, and the guard lines 200tg may be grounded. Thus, touch noise may be reduced or prevented from being introduced through the third electrodes 230 and the fourth electrodes 240.

In one or more embodiments of the present disclosure, at least one of the first mode MD1-d of the first operation mode DMD1 or the first mode MD1 of the second operation mode DMD2 may further include a self-capacitance detecting mode. In the self-capacitance detecting mode, the sensor driver 200C may output driving signals to the first electrodes 210 and the second electrodes 220 and calculate the input coordinates by sensing the change in the capacitance between the first electrodes 210 and the second electrodes 220.

In the self-capacitance detecting mode, the third electrodes 230 and the fourth electrodes 240 may be grounded, and the same signal as the signal provided to adjacent trace lines may be provided to the guard lines 200tg. Thus, a parasitic capacitance provided between trace lines may be reduced or removed by the guard lines 200tg.

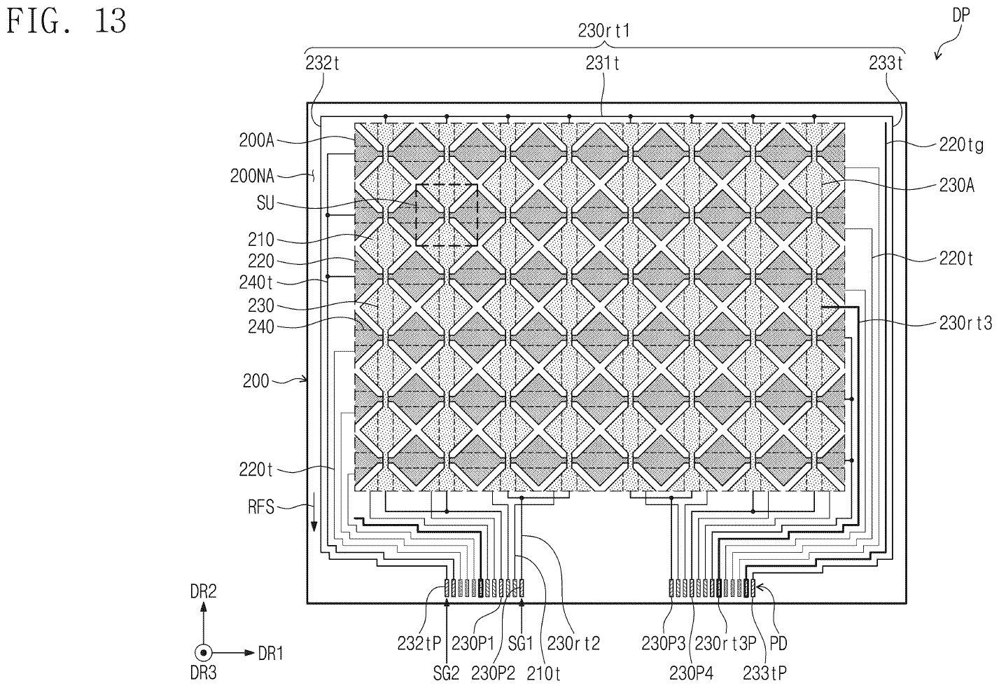

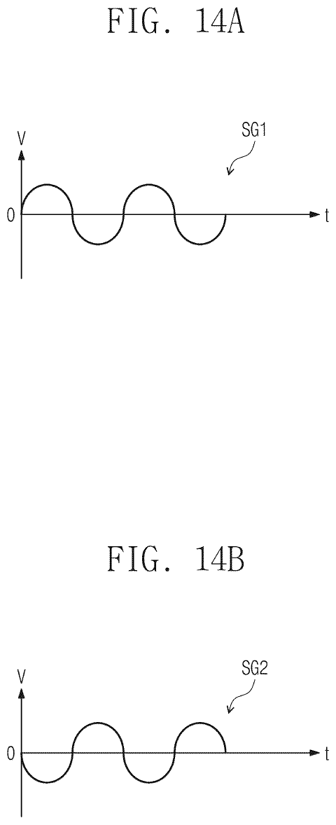

FIG. 13 is a view for describing a second mode according to one or more embodiments of the present disclosure. FIG. 14A is a graph depicting a waveform of a first signal SG1 according to one or more embodiments of the present disclosure. FIG. 14B is a graph depicting a waveform of a second signal SG2 according to one or more embodiments of the present disclosure.

Referring to FIGS. 13, 14A, and 14B, the second mode MD2 may include the charging drive mode. The charging drive mode may include a searching charging drive mode and a tracking charging drive mode.

The searching charging drive mode may be a drive mode before a position of the pen PN (see FIG. 5) is sensed. Thus, the first signal SG1 or the second signal SG2 may be sequentially provided to all channels included in the sensor layer 200. For example, in the searching charging drive mode, an entire area of the sensor layer 200 may be scanned. If (e.g., when) the pen PN (see FIG. 5) is sensed in the searching charging drive mode, the sensor layer 200 may be driven in the tracking charging drive mode. For example, in the tracking charging drive mode, the sensor driver 200C may sequentially output the first signal SG1 and the second signal SG2 to an area overlapping a point at which the pen PN is sensed rather than the entire sensor layer 200.

In the charging drive mode, the sensor driver 200C may apply the first signal SG1 to one pad and the second signal SG2 to the other pad. The second signal SG2 may be an inverse signal of the first signal SG1. For example, the first signal SG1 may be a sinusoidal signal.

Because the first signal SG1 and the second signal SG2 are applied to at least two pads, a current RFS may have a current path flowing to the other one pad through the one pad. Further, because the first signal SG1 and the second signal SG2 are sinusoidal signals having an inverse phase relationship, a direction of the current RFS may be changed periodically. In one or more embodiments of the present disclosure, the first signal SG1 and the second signal SG2 may be square wave signals having an inverse phase relationship.

If (e.g., when) the first signal SG1 and the second signal SG2 have the inverse phase relationship, noise caused in the display layer 100 (see FIG. 4) by the first signal SG1 may be canceled with noise caused by the second signal SG2. Thus, a flicker phenomenon may not occur in the display layer 100, and display quality of the display layer 100 may be improved.

In one or more embodiments of the present disclosure, the first signal SG1 may be a sinusoidal signal. However, the present disclosure is not limited thereto, and the first signal SG1 may be a square wave signal. Further, the second signal SG2 may have a set constant voltage (e.g., a predetermined constant voltage). For example, the second signal SG2 may be a ground voltage. For example, the pad to which the second signal SG2 is applied may be considered as being grounded. Even in this case, the current RFS may flow from the one pad to the other pad. Further, even if (e.g., when) the other one pad is grounded, the first signal SG1 is a sinusoidal wave signal or a square wave signal, and thus the direction of the current RFS may be changed periodically.

Referring to FIG. 13, it is illustrated that the first signal SG1 is provided to the one pad 230P2 connected to the one second loop trace line 230rt2, and the second signal SG2 is provided to the one pad 232tP connected to the first loop trace line 230rt1. The current RFS may flow in a current path defined by the one second loop trace line 230rt2, the one third electrode 230 connected to the one second loop trace line 230rt2, and a portion of the first loop trace line 230rt1. The current path may have a coil shape. Thus, in the charging drive mode of the second mode, a resonance circuit of the pen PN (see FIG. 5) may be charged by a magnetic field provided by the current path.

In one or more embodiments of the present disclosure, the sensor driver 200C may not provide a signal to pads, to which the first signal SG1 and the second signal SG2 are not applied, among the two pads connected to the first loop trace line 230rt1 and the pads connected to the second loop trace lines 230rt2. For example, it may be expressed that ends of some third electrodes, which do not receive the first signal SG1 or the second signal SG2, among the third electrodes 230 are floating. The wording “one end is floating” may mean that no signal is applied to the pads PD connected to ends of some of the third electrodes 230.

According to the present disclosure, the current path having a loop coil pattern may be implemented by components included in the sensor layer 200. Thus, the electronic device 1000 (see FIG. 1A) may charge the pen PN (see FIG. 5) utilizing the sensor layer 200. Thus, because an additional component having a coil for charging the pen PN is not separately required, an increase in the thickness, an increase in the weight, and a decrease in the flexibility of the electronic device 1000 may not occur.

In the charging drive mode, the first electrodes 210, the second electrodes 220, the fourth electrodes 240, and the guard lines 200tg may be grounded or electrically floating or a constant voltage may be applied thereto. In particular, the first electrodes 210, the second electrodes 220, the fourth electrodes 240, and the guard lines 200tg may be floating. For example, no signal may be provided to the pads PD connected to the first electrodes 210, the second electrodes 220, the fourth electrodes 240, and the guard lines 200tg. In this case, the current RFS may not flow through the first electrodes 210, the second electrodes 220, the fourth electrodes 240, and the guard lines 200tg.

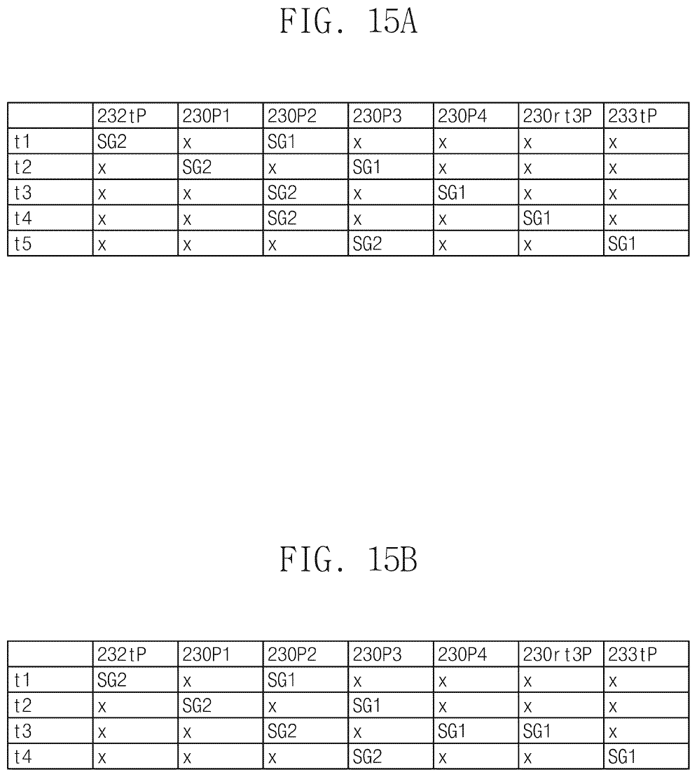

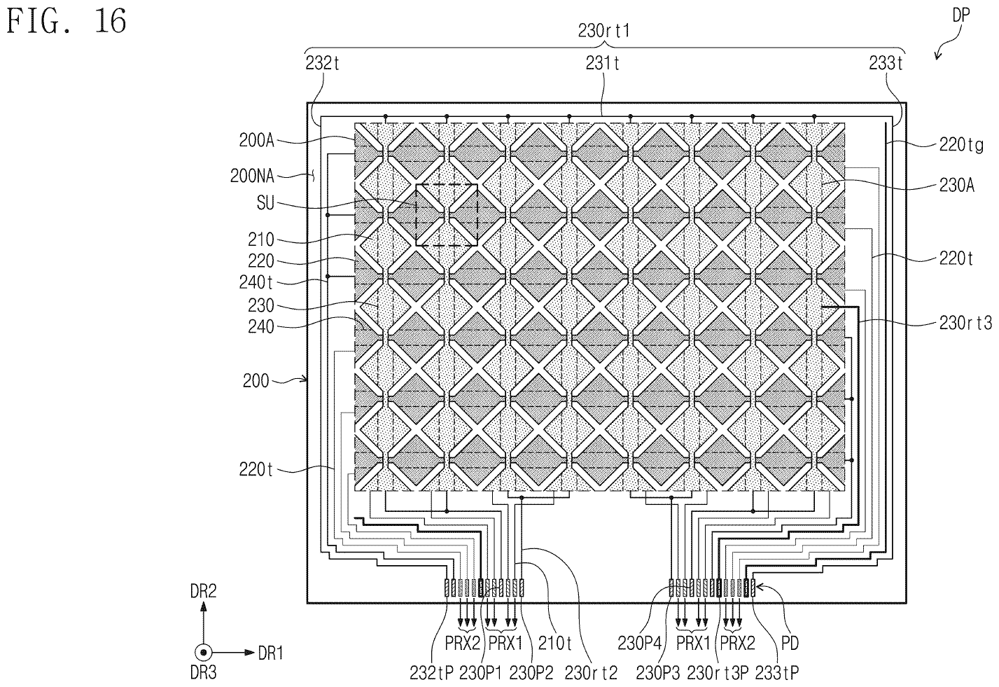

FIG. 15A is a table representing signals provided to the sensor layer 200 according to one or more embodiments of the present disclosure.

Referring to FIGS. 7, 13, and 15A, signals provided to the charging driving pads 232tP, 230P1, 230P2, 230P3, 230P4, 230rt3P, and 233tP in first to fifth time sections t1, t2, t3, t4, and t5 are illustratively expressed.

The signals listed in the table illustrated in FIG. 15A are signals provided to the sensor layer 200 in the searching charging drive mode. Thus, because the position of the pen PN (see FIG. 5) is not sensed, the first signal SG1 or the second signal SG2 may be sequentially provided to all channels included in the sensor layer 200. For example, in the searching charging drive mode, an entire area of the sensor layer 200 may be scanned.

In the second mode, the charging drive mode and the pen-sensing drive mode (see FIG. 16) may be alternately repeated. For example, during the first time section t1, the sensor layer 200 may be driven for charging and then may be operated in the pen-sensing drive mode. If (e.g., when) the pen PN (see FIG. 5) is not sensed, the sensor layer 200 may be driven for charged during the second time section t2. Alternatively, if (e.g., when) the pen PN is sensed, the sensor layer 200 may provide the first signal SG1 or the second signal SG2 to some channels including the sensed position of the pen PN, which may be referred to as the tracking charging drive mode. For example, during the tracking charging drive mode, operations corresponding to at least some of the first to fifth time sections t1, t2, t3, t4, and t5 illustrated in FIG. 15A may be performed depending on the position of the pen PN.

The charging driving pads 232tP, 230P1, 230P2, 230P3, 230P4, 230rt3P, and 233tP may be referred to as the first charging pad 232tP, the second charging pad 230P1, the third charging pad 230P2, the fourth charging pad 230P3, the fifth charging pad 230P4, the sixth charging pad 230rt3P, and the seventh charging pad 233tP.

The first charging pad 232tP and the seventh charging pad 233tP may be respectively connected to both ends of the first loop trace line 230rt1. For example, the first charging pad 232tP may be connected to the second line portion 232t, and the seventh charging pad 233tP may be connected to the third line portion 233t.

The second charging pad 230P1, the third charging pad 230P2, the fourth charging pad 230P3, and the fifth charging pad 230P4 may be electrically connected to the second loop trace lines 230rt2 in one-to-one correspondence. The sixth charging pad 230rt3P may be connected to the third loop trace line 230rt3.

In the first time section t1, the second signal SG2 may be provided to the first charging pad 232tP, and the first signal SG1 may be provided to the third charging pad 230P2. No signal may be provided to the other charging driving pads 230P1, 230P3, 230P4, 230rt3P, and 233tP to which the first signal SG1 and the second signal SG2 are not provided. A magnetic field may be additionally provided in the peripheral area 200NA in the first time section t1. In the second time section t2, the second signal

SG2 may be provided to the second charging pad 230P1, and the first signal SG1 may be provided to the fourth charging pad 230P3.

In the third time section t3, the second signal SG2 may be provided to the third charging pad 230P2, and the first signal SG1 may be provided to the fifth charging pad 230P4. Thereafter, in the fourth time section t4, the second signal SG2 may be provided to the third charging pad 230P2, and the first signal SG1 may be provided to the sixth charging pad 230rt3P. The signals provided to the fifth charging pad 230P4 and the sixth charging pad 230rt3P may be provided to at least substantially the same one third electrode 230A. For example, in the fourth time section t4, a magnetic field may be additionally provided in the peripheral area 200NA.

In one or more embodiments of the present disclosure, the fifth charging pad 230P4 may be connected to the one second loop trace line 230rt2 and may be referred to as a first pad. The sixth charging pad 230rt3P may be connected to the third loop trace line 230rt3 and may be referred to as a second pad. In one or more embodiments of the present disclosure, in the charging drive mode, the sensor driver 200C may provide the first signal SG1 to one of the first pad or the second pad and may not provide the signal to the other. In some embodiments, the other one may be floating.

In the fifth time section t5, the second signal SG2 may be provided to the fourth charging pad 230P3, and the first signal SG1 may be provided to the seventh charging pad 233tP. The seventh charging pad 233tP may be electrically connected to the first loop trace line 230rt1 provided on an outermost side. Thus, in the fifth time section t5, a magnetic field may be additionally provided in the peripheral area 200NA.

As the sensor layer 200 is applied to a medium to large-sized electronic device such as a tablet or a monitor, an area of the peripheral area 200NA may be relatively large. According to one or more embodiments of the present disclosure, a charging drive wiring line such as the third loop trace line 230rt3 may be further added to the sensor layer 200. Thus, as the third loop trace line 230rt3 is utilized, the pen PN (see FIG. 5) may be sufficiently charged in an area adjacent to the peripheral area 200NA. As a result, pen charging performance of the electronic device 1000 (see FIG. 1A) may be improved.

FIG. 15B is a table representing signals provided to the sensor layer 200 according to one or more embodiments of the present disclosure. In description of FIG. 15B, the same reference numerals are designated by the same components described in FIG. 15A, and a description thereof will be omitted.

Referring to FIGS. 13 and 15B, in the third time section t3, the second signal SG2 may be provided to the third charging pad 230P2, and the first signal SG1 may be provided to the fifth charging pad 230P4 and the sixth charging pad 230rt3P. The signals provided to the fifth charging pad 230P4 and the sixth charging pad 230rt3P may be provided to at least substantially the same one third electrode 230A. In some embodiments, in the third time section t3, a magnetic field may be additionally provided in the peripheral area 200NA.

In one or more embodiments of the present disclosure, the fifth charging pad 230P4 may be connected to the one second loop trace line 230rt2 and may be referred to as a first pad. The sixth charging pad 230rt3P may be connected to the third loop trace line 230rt3 and may be referred to as a second pad. In some embodiments of the present disclosure, in the charging drive mode, the sensor driver 200C may provide the first signal SG1 to the first pad and the second pad.

According to one or more embodiments of the present disclosure, in the first to fifth time sections t1, t2, t3, t4, and t5 of FIG. 15A, an operation of the fourth time section t4 may be substituted for an operation of the third time section t3 of FIG. 15B.

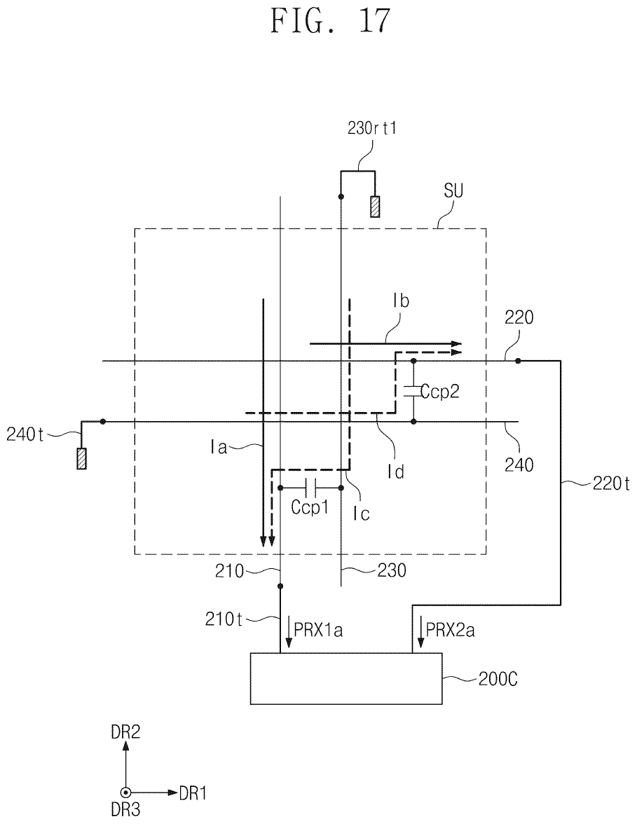

FIG. 16 is a view for describing a second mode according to one or more embodiments of the present disclosure. FIG. 17 is a view for describing a second mode based on the sensor according to one or more embodiments of the present disclosure.

Referring to FIGS. 16 and 17, the second mode may include the charging drive mode and the pen-sensing drive mode. FIGS. 16 and 17 are views for describing the pen-sensing drive mode. Referring to FIG. 16, in the pen-sensing driving mode, first reception signals PRX1 may be output from the first electrodes 210, and second reception signals PRX2 may be output from the second electrodes 220. FIG. 17 illustrates the one sensing unit SU through which first to fourth induced currents Ia, Ib, Ic, and Id generated by the pen PN (see FIG. 5) flow.

In one or more embodiments of the present disclosure, routing directions of the one electrode and the other one electrode of the sensor layer 200, which overlap each other, may be different from each other. For example, a routing direction of the first electrode 210 and a routing direction of the third electrode 230 may be different from each other. Further, a routing direction of the second electrode 220 and a routing direction of the fourth electrode 240 may be different from each other. For example, in FIG. 17, the first electrode 210 and the first trace line 210t may be connected to each other at a lower side of the sensing unit SU, and the third electrode 230 and the first loop trace line 230rt1 may be connected to each other at an upper side of the sensing unit SU. The second electrode 220 and the second trace line 220t may be connected to each other at a right side of the sensing unit SU, and the fourth electrode 240 and the auxiliary trace line 240t may be connected to each other at a left side of the sensing unit SU.

The RLC resonant circuit of the pen PN (see FIG. 5) may emit a magnetic field having a resonant frequency while discharging the charged charges. By the magnetic field provided in the pen PN, the first induced current la may be generated in the first electrode 210, and the second induced current Ib may be generated in the second electrode 220. Further, the third induced current Ic may be generated in the third electrode 230, and the fourth induced current Id may be generated in the fourth electrode 240.

A first coupling capacitor Ccp1 may be provided between the third electrode 230 and the first electrode 210, and a second coupling capacitor Ccp2 may be provided between the fourth electrode 240 and the second electrode 220. The third induced current Ic may be transmitted to the first electrode 210 through the first coupling capacitor Ccp1, and the fourth induced current Id may be transmitted to the second electrode 220 through the second coupling capacitor Ccp2.

The sensor driver 200C may receive, from the first electrode 210, a first reception signal PRX1a based on the first induced current Ia and the third induced current Ic and receive, from the second electrode 220, a second reception signal PRX2a based on the second induced current Ib and the fourth induced current Id. The sensor driver 200C may detect the input coordinates of the pen PN (see FIG. 5) based on the first reception signal PRX1a and the second reception signal PRX2a.

If (e.g., when) the sensor driver 200C receives the first reception signal PRX1a from the first electrode 210 and the second reception signal PRX2a from the second electrode 220, all ends of the third electrode 230 and the fourth electrode 240 may be floating. Thus, compensation of the sensing signal may be improved or maximized by coupling between the first electrode 210 and the third electrode 230 and coupling between the second electrode 220 and the fourth electrode 240.

Further, the other ends of the third electrode 230 and the fourth electrode 240 may be grounded or floating. Thus, the third induced current Ic and the fourth induced current Id may be sufficiently transmitted to the first electrode 210 and the second electrode 220 by the coupling between the first electrode 210 and the third electrode 230 and the coupling between the second electrode 220 and the fourth electrode 240. If (e.g., when) all the ends and the other ends of the third electrode 230 and the fourth electrode 240 are floating, even if (e.g., when) the third electrode 230 is charged in the charging drive mode, the third electrode 230 is floating during the pen-sensing drive mode, and thus a potential may not be sharply changed. Thus, noise caused by a change of the drive mode may be reduced or minimized.

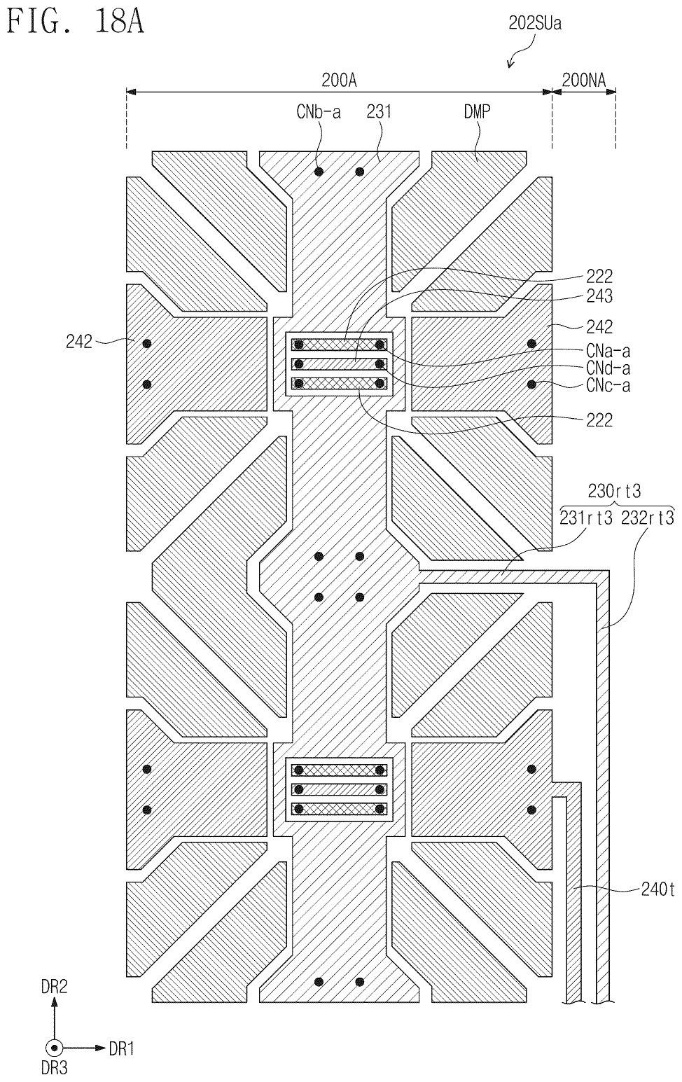

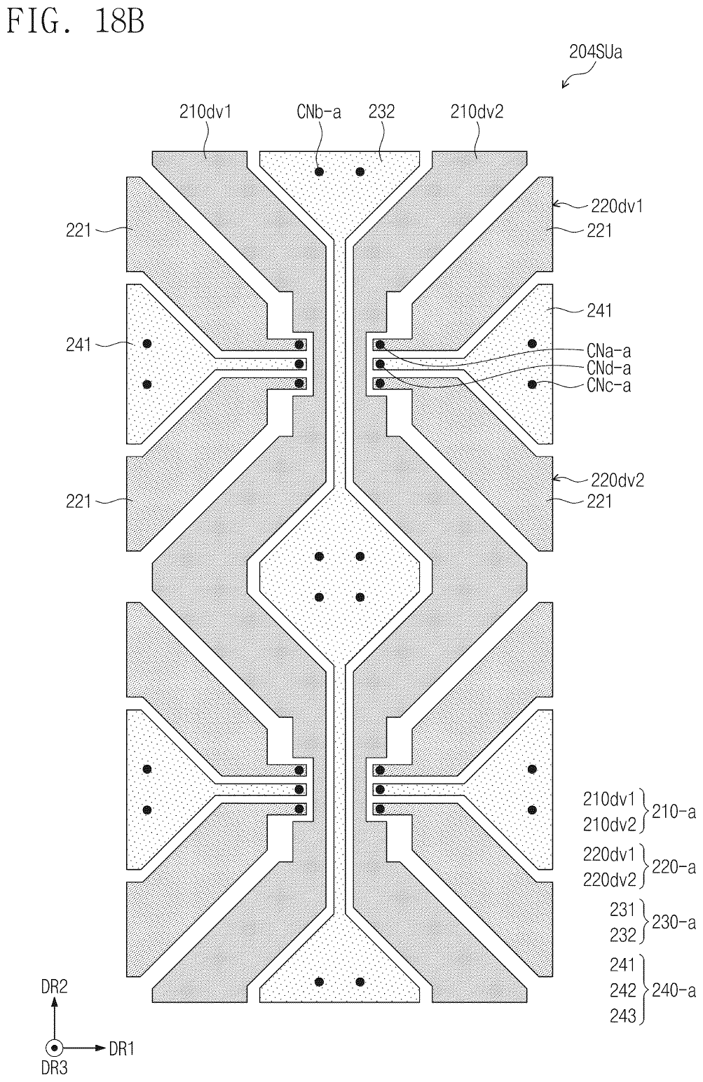

FIG. 18A is a plan view illustrating a first conductive layer 202SUa of the two sensors according to one or more embodiments of the present disclosure. FIG. 18B is a plan view illustrating a second conductive layer 204SUa of the two sensors according to one or more embodiments of the present disclosure.

FIGS. 18A and 18B illustratively illustrate shapes of the first conductive layer 202SUa and the second conductive layer 204SUa of the two sensors adjacent to the peripheral area 200NA. However, the illustrated shapes are an example, and the shapes of the first conductive layer 202SUa and the second conductive layer 204SUa are not limited thereto.

Referring to FIGS. 7, 18A, and 18B, each of first electrodes 210-a may include first split electrodes 210dv1 and 210dv2. The first split electrodes 210dv1 and 210dv2 may extend in the second direction DR2 and may be separated from (e.g., spaced apart from) each other in the first direction DR1. The first split electrodes 210dv1 and 210dv2 may have a shape line-symmetrical to a line extending in the second direction DR2.

Each of second electrodes 220-a may include second split electrodes 220dv1 and 220dv2. The second electrodes 220-a may extend in the first direction DR1 and may be separated from (e.g., spaced apart from) each other in the second direction DR2. The second split electrodes 220dv1 and 220dv2 may have a shape line-symmetrical to a line extending in the first direction DR1.

Each of the second split electrodes 220dv1 and 220dv2 may include a sensing pattern 221 and a bridge pattern 222. The sensing pattern 221 and the bridge pattern 222 may be arranged in different layers, and the sensing pattern 221 and the bridge pattern 222 may be electrically connected to each other through a first contact CNa-a. For example, the bridge pattern 222 may be included in the first conductive layer 202SUa, and the sensing pattern 221 and the first split electrodes 210dv1 and 210dv2 may be included in the second conductive layer 204SUa.

Each of third electrodes 230-a may include a (3-1)^{th} pattern 231 and a (3-2)^{th} pattern 232. The (3-1)^{th} pattern 231 and the (3-2)^{th} pattern 232 may be arranged on different layers, and the (3-1)^{th} pattern 231 and the (3-2)^{th} pattern 232 may be electrically connected to each other through a second contact CNb-a. The (3-1)^{th} pattern 231 may be included in the first conductive layer 202SUa, and the (3-2)^{th} pattern 232 may be included in the second conductive layer 204SUa.

Each of fourth electrodes 240-a may include a (4-1)^{th} pattern 241, a (4-2)^{th} pattern 242, and a (4-3)^{th} pattern 243. The (4-2)^{th} pattern 242 and the (4-3)^{th} pattern 243 may be arranged on the same layer, and the (4-1)^{th} pattern 241 may be provided on a different layer from the (4-2)^{th} pattern 242 and the (4-3)^{th} pattern 243. The (4-1)^{th} pattern 241 and the (4-2)^{th} pattern 242 may be electrically connected to each other through a third contact CNc-a, and the (4-1)^{th} pattern 241 and the (4-3)^{th} pattern 243 may be electrically connected to each other through a fourth contact CNd-a. The (4-2)^{th} pattern 242 and the (4-3)^{th} pattern 243 may be included in the first conductive layer 202SUa, and the (4-1)^{th} pattern 241 may be included in the second conductive layer 204SUa.

In one or more embodiments of the present disclosure, a portion of the (4-2)^{th} pattern 242 may overlap the sensing pattern 221 of each of the second split electrodes 220dv1 and 220dv2. Thus, a coupling capacitor may be defined (or provided or formed) between the second electrode 220-a and the fourth electrode 240-a.

In one or more embodiments of the present disclosure, the first conductive layer 202SUa may further include the dummy patterns DMP. Each of the dummy patterns DMP may be electrically floating or electrically grounded. In one or more embodiments of the present disclosure, the dummy patterns DMP may be omitted. Because the dummy patterns DMP are arranged in an empty space, a probability that specific patterns are visually recognized by reflection of an external light may be decreased. In some embodiments, the electronic device 1000 (see FIG. 1A) having improved visibility due to the reflection of the external light may be provided.

Referring to FIG. 18A, the third loop trace line 230rt3 and the auxiliary trace line 240t are illustratively illustrated. Referring to FIGS. 7 and 18A, the third electrode 230 illustrated in FIG. 18A may be the one third electrode 230A. Thus, the third loop trace line 230rt3 may be connected to the one third electrode 230A.

The third loop trace line 230rt3 may include the first portion 231rt3 provided in the sensing area 200A and the second portion 232rt3 provided in the peripheral area 200NA. The first portion 231rt3 may overlap the first electrode 210-a. For example, the first portion 231rt3 may overlap the first split electrode 210dv2 included in the second conductive layer 204SUa.

In one or more embodiments of the present disclosure, the dummy patterns DMP separated from (e.g., spaced apart from) each other with the first portion 231rt3 of the third loop trace line 230rt3 interposed therebetween may be electrically connected to the first split electrode 210dv2.

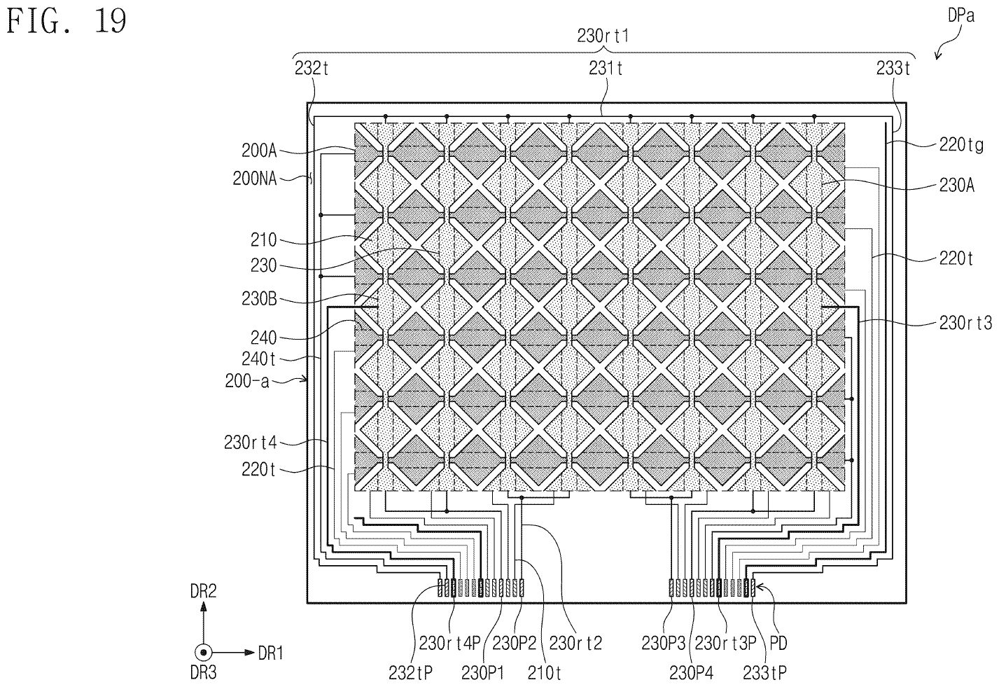

FIG. 19 is a plan view of a display panel DPa according to one or more embodiments of the present disclosure. In description of FIG. 19, the same reference numerals are designated by the same components described in FIG. 7, and a description thereof will be omitted.

Referring to FIG. 19, the display panel DPa includes a sensor layer 200-a. The sensor layer 200-a may further include the first loop trace line 230rt1, the plurality of second loop trace lines 230rt2, the third loop trace line 230rt3, a fourth loop trace line 230rt4, and the auxiliary trace lines 240t. The third loop trace line 230rt3 and the fourth loop trace line 230rt4 may be separated from (e.g., spaced apart from) each other with the sensing area 200A interposed therebetween.

In one or more embodiments of the present disclosure, the third loop trace line 230rt3 may be electrically connected to the one third electrode 230A among the third electrodes 230. The one third electrode 230A may be closest to the peripheral area 200NA in the third electrodes 230. FIG. 19 illustratively illustrates that the one third electrode 230 is an electrode provided on a rightmost side in the sensing area 200A.

In one or more embodiments of the present disclosure, the fourth loop trace line 230rt4 may be electrically connected to the other one third electrode 230B among the third electrodes 230. The other one third electrode 230B among the third electrodes 230 may be closest to the peripheral area 200NA. FIG. 19 illustratively illustrates that the other one third electrode 230B is an electrode provided on a leftmost side in the sensing area 200A.

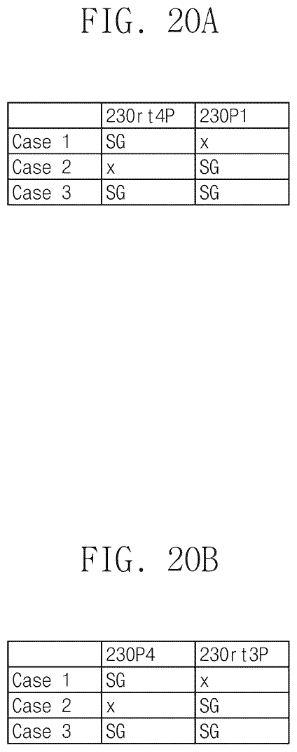

FIG. 20A is a table representing signals provided to the sensor layer 200-a (see FIG. 19) according to one or more embodiments of the present disclosure.

Referring to FIGS. 19 and 20A, in the charging drive mode, the sensor driver 200C may be configured to provide a signal SG to at least one of a second charging pad 230P1 (hereinafter referred to as the first pad) connected to the one second loop trace line 230rt2 or a third pad 230rt4P connected to the fourth loop trace line 230rt4. The signal SG may be the first signal SG1 illustrated in FIG. 14A and the second signal SG2 illustrated in FIG. 14B.

Both the first pad 230P4 and the third pad 230rt4P may be electrically connected to the one third electrode 230B. For example, in case 1, the sensor driver 200C may provide the signal SG to the third pad 230rt4P and not provide the signal SG to the first pad 230P1. Alternatively, in case 2, the sensor driver 200C may not provide the signal to the third pad 230rt4P and provide the signal to the first pad 230P1. Alternatively, in case 3, the sensor driver 200C may provide the signal SG to both the first pad 230P1 and the third pad 230rt4P.

FIG. 20B is a table representing signals provided to the sensor layer 200-a (see FIG. 19) according to one or more embodiments of the present disclosure.

Referring to FIGS. 19 and 20B, in the charging drive mode, the sensor driver 200C may be configured to provide a signal to at least one of a fifth charging pad 230P4 (hereinafter referred to as the first pad) connected to the one second loop trace line 230rt2 or a sixth charging pad 230rt3P (hereinafter referred to as the second pad) connected to the third loop trace line 230rt3. The signal SG may be the first signal SG1 illustrated in FIG. 14A and the second signal SG2 illustrated in FIG. 14B.

Both the first pad 230P4 and the second pad 230rt3P may be electrically connected to the one third electrode 230A. For example, in case 1, the sensor driver 200C may provide the signal SG to the first pad 230P4 and not provide the signal SG to the second pad 230rt3P. Alternatively, in case 2, the sensor driver 200C may not provide the signal to the first pad 230P4 and provide the signal to the second pad 230rt3P. Alternatively, in case 3, the sensor driver 200C may provide the signal SG to both the first pad 230P4 and the second pad 230rt3P.

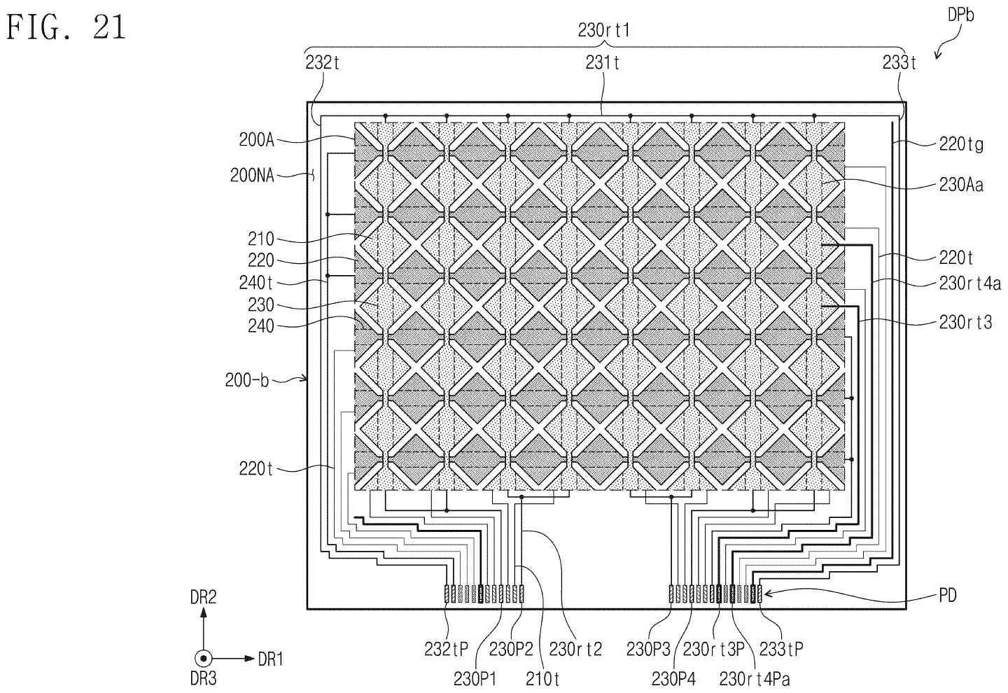

FIG. 21 is a plan view of a display panel DPb according to one or more embodiments of the present disclosure. In description of FIG. 21, the same reference numerals are designated by the same components described in FIG. 7, and a description thereof will be omitted.

Referring to FIG. 21, the display panel DPb includes a sensor layer 200-b. The sensor layer 200-b may further include the first loop trace line 230rt1, the plurality of second loop trace lines 230rt2, the third loop trace line 230rt3, a fourth loop trace line 230rt4a, and the auxiliary trace lines 240t.

In one or more embodiments of the present disclosure, the third loop trace line 230rt3 and the fourth loop trace line 230rt4a may be electrically connected to one third electrode 230Aa among the third electrodes 230. The one third electrode 230Aa among the third electrodes 230 may be closest to the peripheral area 200NA. FIG. 21 illustratively illustrates that the one third electrode 230Aa is an electrode provided on a rightmost side in the sensing area 200A, but the present disclosure is not particularly limited thereto.

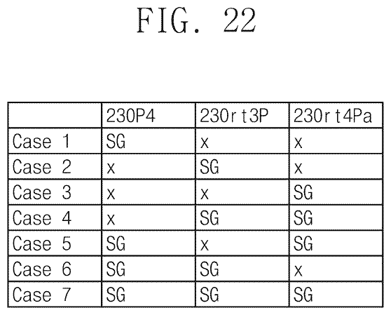

FIG. 22 is a table representing signals provided to the sensor layer 200-b (see FIG. 21) according to one or more embodiments of the present disclosure.

Referring to FIGS. 21 and 22, in the charging drive mode, the sensor driver 200C may be configured to provide a signal to at least one of the first pad 230P4 connected to the one second loop trace line 230rt2, the second pad 230rt3P connected to the third loop trace line 230rt3, or a third pad 230rt4Pa connected to the fourth loop trace line 230rt4a. The signal SG may be the first signal SG1 illustrated in FIG. 14A and the second signal SG2 illustrated in FIG. 14B.

All the first pad 230P4, the second pad 230rt3P, and the third pad 230rt4Pa

may be electrically connected to the one third electrode 230Aa. In one or more embodiments of the present disclosure, the sensor driver 200C may provide the signal SG to one pad among the first to third pads 230P4, 230rt3P, and 230rt4Pa and may not provide the signal to the other two pads. This is represented in cases 1 to 3 as an example. The pads that do not receive the signal from the sensor driver 200C may be expressed as “floating.”

In one or more embodiments of the present disclosure, the sensor driver 200C may provide the signal SG to two pads among the first to third pads 230P4, 230rt3P, and 230rt4Pa and may not provide the signal to the other one pad. This is represented in cases 4 to 6 as an example. In one or more embodiments of the present disclosure, the sensor driver 200C may provide the signal SG to all the first to third pads 230P4, 230rt3P, and 230rt4Pa. This is represented in case 7 as an example.

According to the above description, an input by a pen as well as a touch input may be sensed utilizing a sensor layer. Thus, because an electronic device does not require an additional separate component (e.g., a digitizer) for pen sensing, an increase in a thickness, an increase in a weight, and a decrease in flexibility of the electronic device due to addition of the digitizer may not occur. Further, a first loop trace line, a second loop trace line, and a third loop trace line may be connected to at least one charging electrode of the sensor layer. In this case, as the sensor layer is applied to a medium to large-sized electronic device such as a tablet or a monitor, even if (e.g., when) an area of a peripheral area is increased, a pen may be sufficiently charged in a space adjacent to the peripheral area by additionally utilizing the third loop trace line. Thus, pen charging performance of the electronic device may be improved.

In the context of the present disclosure and unless otherwise defined, the terms “use/utilize,” “using/utilizing,” and “used/utilized” may be considered synonymous with the terms “utilize,” “utilizing,” and “utilized,” respectively.

A person of ordinary skill in the art would appreciate, in view of the present disclosure in its entirety, that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Although the description has been made above with reference to one or more embodiments of the present disclosure, it may be understood that those skilled in the art or those having ordinary knowledge in the art may suitably modify and change the present disclosure without departing from the spirit and technical scope of the present disclosure and equivalents thereof described in the appended claims. Therefore, the disclosed embodiments are utilized in a generic and descriptive sense only and not for purposes of limitation. Thus, the present disclosure is not limited to the detailed description of the specification but should be defined by the appended claims, with functional equivalents thereof to be included therein.

What is claimed is:

1. An electronic device comprising:
a sensor layer defining a sensing area, and a peripheral area adjacent to the sensing area, and comprising:
first electrodes in the sensing area, and arranged in a first direction;
second electrodes in the sensing area, and arranged in a second direction crossing the first direction;
third electrodes in the sensing area, and arranged in the first direction;
first trace lines electrically connected to the first electrodes in one-to-one correspondence;
second trace lines electrically connected to the second electrodes in one-to-one correspondence;
a first loop trace line electrically connected to the third electrodes;
second loop trace lines electrically connected to the third electrodes; and
a third loop trace line electrically connected to one of the third electrodes.

2. The electronic device of claim 1, wherein the one of the third electrodes is closest to the peripheral area among the third electrodes, and is electrically connected to the first loop trace line and to one of the second loop trace lines.

3. The electronic device of claim 2, further comprising a sensor driver configured to drive the sensor layer, and configured to selectively operate in a first mode for sensing a touch input or in a second mode for sensing a pen input, the second mode comprising a charging drive mode and a pen-sensing drive mode.

4. The electronic device of claim 3, wherein, in the charging drive mode, the sensor driver is configured to provide a signal to one of a first pad connected to the one of the second loop trace lines, or a second pad connected to the third loop trace line, to the exclusion of the other one of the first pad or the second pad.

5. The electronic device of claim 3, wherein, in the charging drive mode, the sensor driver is configured to provide a signal to a first pad connected to the one of the second loop trace lines, and to a second pad connected to the third loop trace line.

6. The electronic device of claim 3, wherein the sensor layer further comprises a fourth loop trace line electrically connected to the one of the third electrodes.

7. The electronic device of claim 6, wherein, in the charging drive mode, the sensor driver is configured to provide a signal to at least one of a first pad connected to the one of the second loop trace lines, a second pad connected to the third loop trace line, or a third pad connected to the fourth loop trace line.

8. The electronic device of claim 1, wherein the sensor layer further comprises a fourth loop trace line electrically connected to another one of the third electrodes.

9. The electronic device of claim 1, wherein a first portion of the third loop trace line is at the sensing area, and a second portion of the third loop trace line is at the peripheral area.

10. The electronic device of claim 9, wherein the first portion of the third loop trace line overlaps at least one of the first electrodes.

11. The electronic device of claim 9, wherein the second portion of the third loop trace line is between the sensing area and the first loop trace line in plan view.

12. The electronic device of claim 1, wherein the sensor layer further comprises:
fourth electrodes in the sensing area, and arranged in the second direction; and
an auxiliary trace line electrically connected to the fourth electrodes.

13. The electronic device of claim 12, wherein the third loop trace line is between the auxiliary trace line and at least one of the second trace lines in plan view.

14. The electronic device of claim 1, wherein a width of the sensing area in the first direction is greater than a width of the sensing area in the second direction, and
wherein the third loop trace line is separated from the sensing area in the first direction.

15. An electronic device comprising:
a sensor layer defining a sensing area, and a peripheral area adjacent to the sensing area, and comprising:
first electrodes in the sensing area, and arranged in a first direction;
second electrodes in the sensing area, and arranged in a second direction crossing the first direction;
third electrodes in the sensing area, and arranged in the first direction; and
trace lines electrically connected to the first electrodes, to the second electrodes, and to the third electrodes, and comprising:
a first loop trace line connected to one end of one of the third electrodes;
a second loop trace line connected to another end of the one of the third electrodes; and
a third loop trace line connected to the one of the third electrodes.

16. The electronic device of claim 15, wherein the trace lines further comprises a fourth loop trace line connected to the one of the third electrodes.

17. The electronic device of claim 15, further comprising a sensor driver configured to drive the sensor layer, and configured to selectively operate in a first mode of sensing a touch input, or a second mode of sensing a pen input, the second mode comprising a charging drive mode and a pen-sensing drive mode.

18. The electronic device of claim 17, wherein, in the charging drive mode, the sensor driver is configured to provide a signal to one of a first pad connected to the second loop trace line, or a second pad connected to the third loop trace line, to the exclusion of the other one of the first pad or the second pad.

19. The electronic device of claim 17, wherein, in the charging drive mode, the sensor driver is configured to provide a signal to a first pad connected to the second loop trace line, and to a second pad connected to the third loop trace line.

20. The electronic device of claim 15, wherein the trace lines further comprise a fourth loop trace line connected to another one of the third electrodes, and
wherein the third loop trace line is separated from the fourth loop trace line with the sensing area therebetween in plan view.
